(19) United States
(12) Patent Application Publication
(10) Pub. No.: US 2016/0190239 A1
(43) Pub. Date: Jun. 30, 2016

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Sung-Dae SUK, Seoul (KR); Kang-III SEO, Chungcheongbuk-do (KR)

(21) Appl. No.: 14/583,258

(22) Filed: Dec. 26, 2014

(51) Int. Cl. H01L 29/06; H01L 29/16; H01L 29/423; H01L 29/49; H01L 27/092; H01L 27/12

(52) U.S. Cl. CPC H01L 29/0649; H01L 27/0924; H01L 27/1211; H01L 29/0673; H01L 29/42392; H01L 29/495; H01L 29/16

(57) ABSTRACT

A semiconductor device is provided. The semiconductor device includes a sacrificial layer formed on a substrate, an active layer formed on the sacrificial layer, a gate insulating layer and a gate electrode formed to surround a part of the active layer, a spacer disposed on at least one side of the gate electrode, a source or drain separated from the gate electrode by the spacer and disposed on the substrate, and an air gap arrange between a lower portion of the active layer and the sacrificial layer, wherein the sacrificial layer is disposed on a lower portion of the source or drain and is not disposed on a lower portion of the gate electrode.

### TECHNICAL FIELD

The present inventive concept relates to a semiconductor device and a method for fabricating the same.

### DISCUSSION OF RELATED ART

Recently, semiconductor devices have been developed that can perform high-speed operations at low voltage, and processes of fabricating a semiconductor device have been developed that can increase structural integrity of the semiconductor device.

The increased structural integrity of the semiconductor device may cause the occurrence of a short channel effect in a field effect transistor (FET) of the semiconductor device. In order to overcome this in fin field effect transistors (FinFET) a 3D spatial structure has been made.

### SUMMARY

One aspect of the present inventive concept is to provide a semiconductor device, which can improve operation characteristics.

Another aspect of the present inventive concept is to provide a method for fabricating a semiconductor device, which can improve the operation characteristics.

Additional aspects, subjects, and features of the inventive concept will be set forth in part in the description which follows and in part will become apparent to those having ordinary skill in the art upon examination of the following or may be learned from practice of the inventive concept.

According to an aspect of the present inventive concept, there is provided a semiconductor device, the semiconductor device including a sacrificial layer formed on a substrate, an active layer formed on the sacrificial layer, a gate insulating layer and a gate electrode formed to surround a part of the active layer, a spacer disposed on at least one side of the gate electrode, a source or drain separated from the gate electrode by the spacer and disposed on the substrate, and an air gap arrange between a lower portion of the active layer and the sacrificial layer, wherein the sacrificial layer is disposed on a lower portion of the source or drain and is not disposed on a lower portion of the gate electrode.

According to another aspect of the present inventive concept, there is provided a semiconductor device, the semiconductor device including a substrate on which first and second regions are defined, a first nanowire transistor disposed on the first region, and a second nanowire transistor disposed on the second region, wherein the first nanowire transistor including a first sacrificial layer formed on the substrate, a first active layer formed on the first sacrificial layer, a first gate electrode formed to surround a part of the first active layer, and a first air gap formed between a lower portion of the first active layer and the first sacrificial layer, and the second nanowire transistor including a second sacrificial layer formed on the substrate and including a material that is different from the material of the first sacrificial layer, a second active layer formed on the second sacrificial layer, a second gate electrode formed to surround a part of the second active layer, and a second air gap formed between a lower portion of the second active layer and the second sacrificial layer.

### BRIEF DESCRIPTION OF THE DRAWINGS

The above and other features and aspects of the present inventive concept will be more apparent from the following detailed description taken in conjunction with the accompanying drawings, in which:

FIG. 1 is a perspective view illustrating a semiconductor device according to a first embodiment of the present inventive concept;

FIG. 2 is a cross-sectional view taken along line A-A of FIG. 1;

FIG. 3 is a cross-sectional view taken along line B-B of FIG. 1;

FIG. 4 is a perspective view illustrating a semiconductor device according to an exemplary embodiment of the present inventive concept;

FIG. 5 is a cross-sectional view taken along line A-A of FIG. 4;

FIG. 6 is a cross-sectional view taken along line B-B of FIG. 4;

FIG. 7 is a perspective view illustrating a semiconductor device according to an exemplary embodiment of the present inventive concept;

FIG. 8 is a cross-sectional view taken along line A-A of FIG. 7;

FIG. 9 is a cross-sectional view taken along line B-B of FIG. 7;

FIG. 10 is a perspective view illustrating a semiconductor device according to an exemplary embodiment of the present inventive concept;

FIG. 11 is a cross-sectional view taken along line A-A of FIG. 10;

FIG. 12 is a cross-sectional view taken along line B-B of FIG. 10;

FIG. 13 is a perspective view illustrating a semiconductor device according to an exemplary embodiment of the present inventive concept;

FIG. 14 is a cross-sectional view taken along line A-A of FIG. 13;

FIG. 15 is a cross-sectional view taken along line B-B of FIG. 13;

FIG. 16 is a perspective view illustrating a semiconductor device according to an exemplary embodiment of the present inventive concept;

FIG. 17 is a cross-sectional view taken along line C-C of FIG. 16;

FIG. 18 is a perspective view illustrating a semiconductor device according to an exemplary embodiment of the present inventive concept;

FIG. 19 is a cross-sectional view taken along line C-C of FIG. 16;

FIG. 20 is a perspective view illustrating a semiconductor device according to an exemplary embodiment of the present inventive concept;

FIG. 21 is a cross-sectional view taken along line C-C of FIG. 16;

FIG. 22 is a perspective view illustrating a semiconductor device according to an exemplary embodiment of the present inventive concept;

FIG. 23 is a cross-sectional view taken along line C-C of FIG. 16;

FIG. 24 is a circuit diagram explaining a semiconductor device according to exemplary embodiments of the present inventive concept;

FIG. 25 is a layout diagram of a semiconductor device illustrated in FIG. 24;

FIG. 26 is a circuit diagram explaining a semiconductor device according to exemplary embodiments of the present inventive concept;

FIG. 27 is a circuit diagram explaining a semiconductor device according to exemplary embodiments of the present inventive concept;

FIG. 28 is a block diagram of a SoC system that includes a semiconductor device according to embodiments of the present inventive concept;

FIG. 29 is a block diagram of an electronic system that includes a semiconductor device according to embodiments of the present inventive concept;

FIGS. 30 to 32 are views of exemplary semiconductor systems to which a semiconductor device according to exemplary embodiments of the present inventive concept can be applied;

FIGS. 33 to 42 are views of intermediate steps of a method for fabricating a semiconductor device according to an embodiment of the present inventive concept; and

FIGS. 43 to 45 are views of intermediate steps explaining a method for fabricating a semiconductor device according to an exemplary embodiment of the present inventive concept.

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Like reference numerals may refer to like elements throughout the specification and drawings.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Exemplary embodiments are described herein with reference to cross-section illustrations that may be schematic illustrations of idealized embodiments (and intermediate structures). As such, variations from the shapes of the illustrations as a result, for example, of manufacturing techniques and/or tolerances, may occur. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

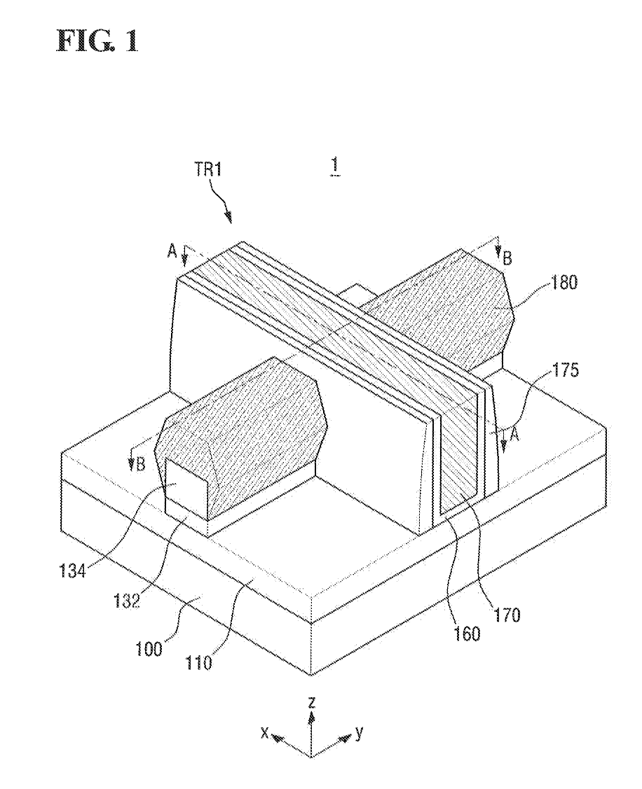

Hereinafter, referring to FIGS. 1 to 23, a semiconductor device according to exemplary embodiments of the present inventive concept will be described in more detail.

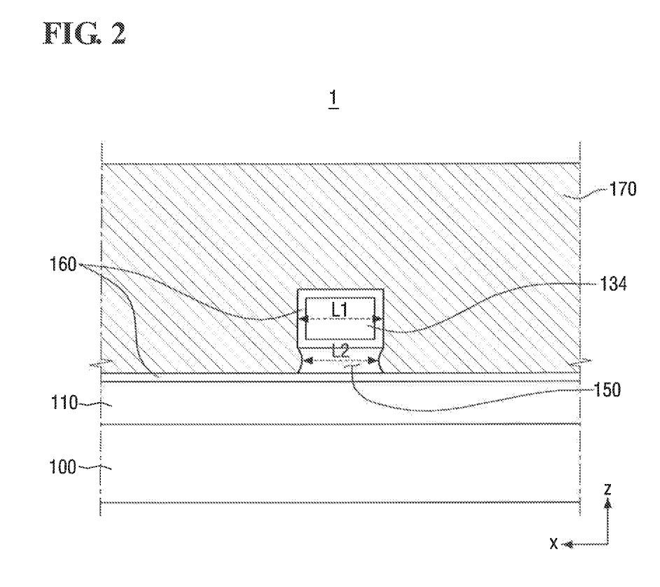

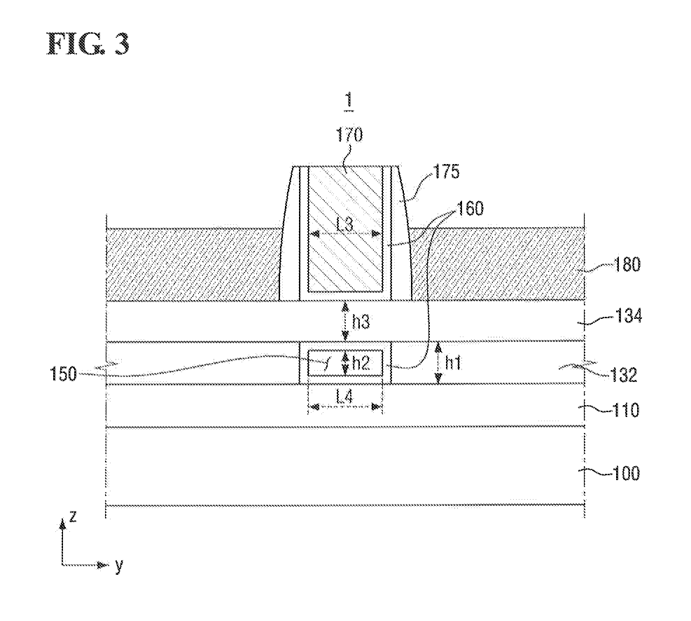

FIG. 1 is a perspective view illustrating a semiconductor device according to an exemplary embodiment of the present inventive concept. FIG. 2 is a cross-sectional view taken along line A-A of FIG. 1, and FIG. 3 is a cross-sectional view taken along line B-B of FIG. 1.

Referring to FIGS. 1 to 3, a semiconductor device 1 includes a substrate 100, a sacrificial layer 132, an active layer 134, a source/drain 180, a gate insulating layer 160, a gate electrode 170, and an air gap 150.

Hereinafter, the semiconductor device 1 according to exemplary embodiments of the present inventive concept will be described, and the case of a first transistor TR1 including an air gap 150 is described. However, the present inventive concept is not limited to any particular illustrated example.

Referring to FIGS. 1 to 3, the substrate 100 may include, for example, bulk silicon or SOI (Silicon-On-Insulator). Unlike this, the substrate 100 may be a silicon substrate 100, or may include another material, such as silicon germanium, indium antimonide, lead telluride, indium arsenide, indium phosphide, gallium arsenide, or gallium antimonide. Further, the substrate 100 may be provided by forming an epitaxial layer on a base substrate. However, the present inventive concept is not limited thereto.

An isolation layer 110 may be positioned on the substrate 100. Specifically, the isolation layer 110 may be positioned between the substrate 100 and the sacrificial layer 132. In some embodiments of the present inventive concept, the isolation layer 110 may be, for example, an insulating layer. More specifically, the isolation layer 110 may be, for example, a silicon oxide layer (SiO2), a silicon nitride layer (SiN), or a silicon oxynitride layer (SiON), but the present inventive concept is not limited thereto.

In some embodiments of the present inventive concept, the isolation layer 110 may be, for example, a STI (Shallow Trench Isolation) layer. However, the present inventive concept is not limited thereto. In some embodiments of the present inventive concept, the isolation layer 110 may be a DTI (Deep Trench Isolation) layer, That is, the isolation layer 110 according to embodiments of the present inventive concept is not limited to a particular embodiment.

The sacrificial layer 132 may be formed on the isolation layer 110. In an exemplary embodiment, the sacrificial layer 132 may include, for example, a semiconductor material. Specifically, the sacrificial layer 132 may include, for example, silicon germanium (SiGe). If the sacrificial layer 132 is made of silicon germanium (SiGe) as described above, the weight of the germanium (Ge) occupied in the sacrificial layer 132 may be higher than the weight of the silicon (Si) occupied in the sacrificial layer 132. This is to heighten the etching selectivity in the following fabricating process. On the other hand, the sacrificial layer 132 according to an exemplary embodiment is not limited to that as described above. As desired, the configuration of the sacrificial layer 132 may be modified without limits.

As illustrated, the sacrificial layer 132 may be formed on a lower portion of the active layer 134 on which the source/drain 180 is formed, but need not be formed on the lower portion of the active layer 134 on which the gate electrode 170 is formed. That is, on the lower portion of the active layer 134 on which the gate electrode 170 is formed, an air gap 150 may be disposed instead of the sacrificial layer 132. Further, the gate insulating layer 160 may be formed between the active layer 134 and the air gap 150 and between the sacrificial layer 132 and the air gap 150. The sacrificial layer 132 may be formed with a thickness that is thinner than the thickness of the active layer 134. Specifically, the sacrificial layer 132 may be formed with a sufficiently thin thickness so that the sacrificial layer 132 is not filled with the gate electrode 170, but the air gap 150 is formed thereon. For example, the gate electrode 170 includes tungsten (W), and the sacrificial layer 132 may be formed with a thickness of 2 to 4 nm. If the thickness of the sacrificial layer 132 is equal to or smaller than 4 nm, the air gap 150 can be formed when the gate insulating layer 160 is formed on the lower portion of the active layer 134. Further, if the thickness of the sacrificial layer 132 is 2 nm or more, the lower portion of the active layer 134 is prevented from filling gap into the gate insulating layer 160. However, the present inventive concept is not limited thereto.

The active layer 134 may be formed on the sacrificial layer 132. The active layer 134 may be used as a channel of the first transistor TR1. The thickness h3 of the active layer 134 may be thicker than the thickness h1 of the sacrificial layer 132. The active layer 134 may include silicon or germanium that is an elemental semiconductor material. Further, the active layer 134 may include a compound semiconductor, and for example, may include group IV-IV compound semiconductor or group III-V compound semiconductor. Specifically, according to the group IV-IV compound semiconductor, the epitaxial layer may include a binary compound including at least two of carbon (C), silicon (Si), germanium (Ge), and tin (Sn), a ternary compound, or a compound including the above-described elements doped with group IV elements. According to the group III-V compound semiconductor, the epitaxial layer may include a binary compound formed through combination of at least one of group III elements, such as aluminum (Al), gallium (Ga), and indium (In), and one of group V elements, such as phosphorus (F), arsenide (As), and antimonium (Sb), a ternary compound, or a quaternary is compound.

In some embodiments of the present inventive concept, the active layer 134 may include the same material as the substrate 100. For example, if the substrate 100 includes silicon, the active layer 134 may also include silicon. Further, if the substrate 100 includes group III-V compound semiconductor, the active layer 134 may also include group III-V compound semiconductor.

The gate insulating layer 160 may be formed to completely surround the active layer 134. Further, as illustrated, the gate insulating layer 160 may be formed to extend upward along a side wall of a spacer 175. Further, the gate insulating layer 160 may be formed to completely surround the circumference of the air gap 150. That is, the gate insulating layer 160 may be formed on a side wall of the sacrificial layer 132 and the isolation layer 110 in a region where the sacrificial layer 132 is etched. However, the present inventive concept is not limited thereto.

In some embodiments of the present inventive concept, the gate insulating layer 160 may include a high-k layer. If the gate insulating layer 160 includes a high-k layer, the gate insulating layer 160 may include a material having high dielectric constant. In some embodiments of the present inventive concept, such a material having high dielectric constant may be, for example, HfO2, Al2O3, ZrO2, or TaO2, but the present inventive concept is not limited thereto.

Although not illustrated in detail in the drawing, an interface layer (not illustrated) may be formed between the gate insulating layer 160 and the active layer 134. The interface layer (not illustrated) may serve to prevent inferior interface between the substrate 100 and the gate insulating layer 160. The interface layer (not illustrated) may include a low-k material layer of which the dielectric constant k is equal to or lower than 9, for example, a silicon oxide layer (where, k is approximately 4) or a silicon oxynitride layer (where, k is approximately 4 to 8 depending on the contents of oxygen atoms and nitrogen atoms). Further, the interface layer (not illustrated) may include silicate, or may include a combination of the above-exemplified layers.

The gate electrode 170 may be formed on the gate insulating layer 160. As illustrated, the gate electrode 170 may be formed to surround a portion except for a lower portion of a part of the active layer 134. Specifically, if only one active layer 134 is formed, the gate electrode 170 may surround only an upper surface and both side surfaces of the active layer 134, but need not be formed on the lower portion of the active layer 134. The air gap 150 may be formed on the lower portion of the active layer 134 that is not filled with the gate electrode 170.

In some embodiments of the present inventive concept, the gate electrode 170 may include a metal gate electrode 170. Specifically, the gate electrode 170 may include a metal having high conductivity. Examples of such a metal may be Al and W, but the present inventive concept is not limited thereto.

Although not illustrated in detail in the drawing, the gate electrode 170 may include a work function layer (not illustrated) that can adjust a work function of the first transistor TR1. For example, if the first transistor TR1 is of a PMOS type, the work function layer (not illustrated) may include a P-type work function layer. The P-type work function layer may be configured to include at least one of TiN, TaN, TiC, and TaC. More specifically, the P-type work function layer may be formed of, for example, a single layer made of TiN or a double layer composed of a lower TiN layer and an upper TaN layer, but the present inventive concept is not limited thereto.

The air gap 150 may be disposed on the lower portion of the active layer 134. The air gap 150 may be disposed to overlap the active layer 134. Specifically, the air gap 150 may be surrounded by the sacrificial layer 132, the active layer 134, the gate electrode 170, and the isolation layer 110. The thickness h2 of the air gap 150 may he thinner than the thickness h1 of the sacrificial layer 132. The gate electrode 170 may he formed convexly toward the lower side of the active layer 134. Specifically, the width L2 of the air gap 150 may be smaller than the sum L1 of thicknesses of the active layer 134 and the gate insulating layer 160. Further, the width L4 of the air gap 150 in the y-axis direction may be substantially equal to the width L3 of the gate electrode 170 in the y-axis direction. However, the present inventive concept is not limited thereto.

The air gap 150 may be formed with different heights according to a gap-fill limit value of the gate electrode 170. That is, if the thickness h1 of the sacrificial layer 132 is smaller than the gap-fill limit value of the gate electrode 170, a space that is formed in the lower portion of the active layer 134 through etching of the sacrificial layer 132 is not filled with the gate electrode 170, and thus the air gap 150 may be formed in the space. However, since the gap-fill ability of the gate insulating layer 160 is better than the gap-fill ability of the gate electrode 170, the gate insulating layer 160 may be formed to completely surround a part of the active layer 134. However, the present inventive concept is not limited thereto.

The source/drain 180 may be formed on both sides of the gate electrode 170. In an exemplary embodiment, the source/drain 180 may be formed, for example, through an epitaxial growth process. Accordingly, as illustrated, the source/drain 180 may be formed to be higher than the sacrificial layer 132 and to surround the active layer 134. On the other hand, the shape of the source/drain 180 according to the present inventive concept is not limited thereto, but as desired, the shape of the source/drain 180 may be modified without limits. For example, in some embodiments of the present inventive concept, the source/drain 180 may be formed by performing an IIP (Ion Implantation) process with respect to the active layer 134.

The source/drain 180 may be separated from the gate electrode 170 by the spacer 175. In other words, as illustrated, the spacer 175 may be disposed on at least one side of the gate electrode 170, and may be disposed between the gate electrode 170 and the source/drain 180. The sacrificial layer 132 may be disposed on the lower portion of the source or drain, but need not be disposed on the lower portion of the gate electrode 170.

The spacer 175 may include at least one of a nitride layer and an oxynitride layer. FIGS. 1 and 3 illustrate that one side surface of the spacer 175 is curved, but the present inventive concept is not limited thereto. That is, the shape of the spacer 175 may be differently modified without limits. For example, in some embodiments of the present inventive concept, the spacer 175 may be modified to be in “I” shape or in “L” shape unlike that as illustrated in the drawing.

For example, if the first transistor TR1 is of a PMOS type, the source/drain 180 may include a P-type impurity. Further, through adjustment of the amount of germanium (Ge) included in the sacrificial layer 132, the amount of stress applied to the active layer 134 can be adjusted.

On the other hand, although not illustrated in detail in the drawing, an interlayer insulating layer (not illustrated) may be formed on the upper portion of the isolation layer 110. The interlayer insulating layer (not illustrated) may be formed to cover the sacrificial layer 132, the source/drain 180, and the gate electrode 170.

As described above, according to the semiconductor device 1 according to an exemplary embodiment, the air gap 150 is formed on the lower portion of the active layer 134. Accordingly, unwanted capacitance that may occur in the case where the gate electrode 170 completely surrounds the active layer 134 can be reduced. Further, channel stress that is applied to the active layer 134 can be reduced. As a result, the short channel effect that occurs in the semiconductor device 1 can be reduced to improve the operation characteristics of the first transistor TR1.

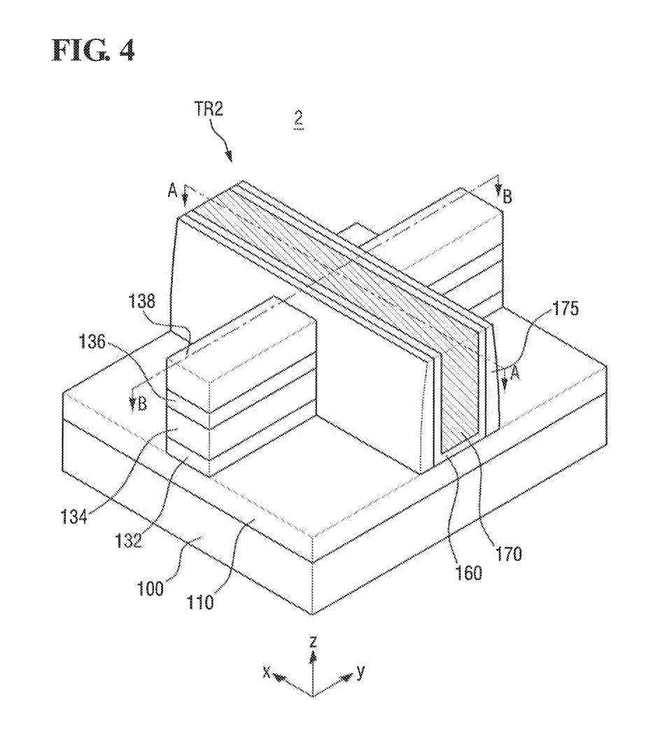

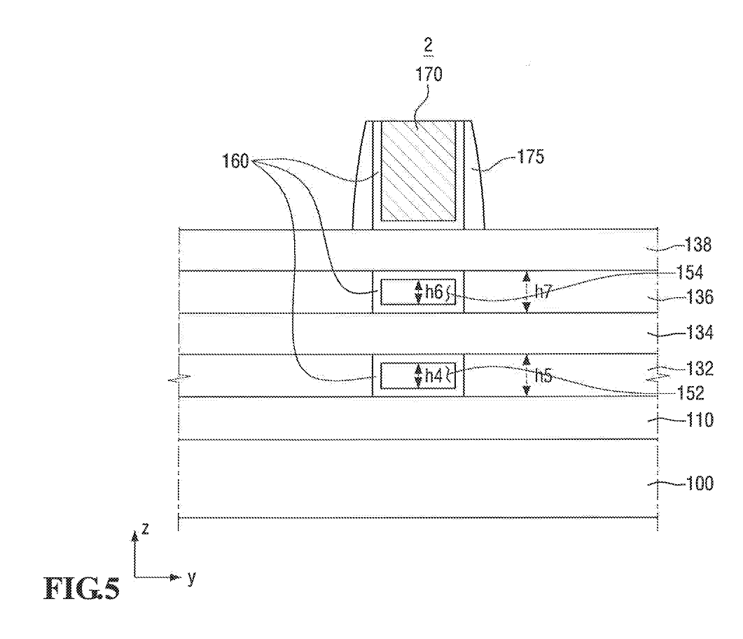

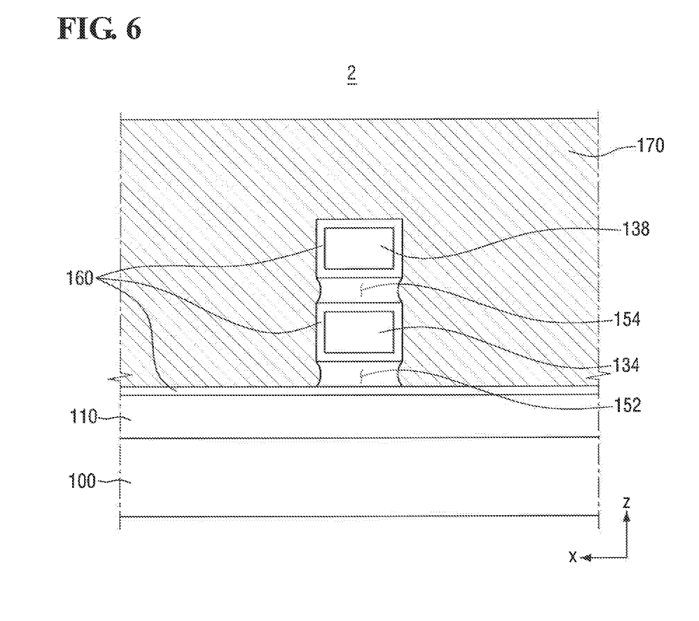

FIG. 4 is a perspective view illustrating a semiconductor device according to an exemplary embodiment of the present inventive concept. FIG. 5 is a cross-sectional view taken along line A-A of FIG. 4, and FIG. 6 is a cross-sectional view taken along line B-B of FIG. 4.

Hereinafter, a semiconductor device 2 according to an exemplary embodiment of the present inventive concept will be described, and a second transistor TR2 including an air gap 150 will be described. However, the present inventive concept is not limited to a particular embodiment.

Referring to FIGS. 4 to 6, unlike the semiconductor device 1 as described above, a semiconductor device 2 according to an exemplary embodiment may include a plurality of sacrificial layers 132 and 136 and a plurality of active layers 134 and 138.

Specifically, a structure, in which the sacrificial layers 132 and 136 and the active layers 134 and 138 are repeated to be alternately laminated, may be formed on the substrate 100. The active layers 134 and 138 are made of Si, and the sacrificial layers 132 and 136 are made of SiGe, but are not limited thereto. The number of repetitions the active layers 134 and 138 and the sacrificial layers 132 and 136 are alternately laminated may differ depending on the number of nanowires to be formed thereafter. The semiconductor device 2 according to an exemplary embodiment includes two sacrificial layers 132 and 136 and two active layers 134 and 138. However, the present inventive concept is not limited thereto, and the semiconductor device 2 according to an exemplary embodiment may include N (where, N is a natural number) active layers or sacrificial layers.

The sacrificial layers 132 and 136 may include the first sacrificial layer 132 and the second sacrificial layer 136. The second sacrificial layer 136 may be positioned on the first sacrificial layer 132.

The active layers 134 and 138 may include the first active layer 134 and the second active layer 138. The first active layer 134 may be positioned between the first sacrificial layer 132 and the second sacrificial layer 136, and the second active layer 138 may be positioned on the second sacrificial layer 136. That is, the first sacrificial layer 132, the first active layer 134, the second sacrificial layer 136, and the second active layer 138 may be formed in order on the substrate.

The first active layer 134 and the second active layer 138 may be formed at the same height. Further, the first sacrificial layer 132 and the second sacrificial layer 136 may be formed at the same height. However, the present inventive concept is not limited thereto. Although the height H5 of the first sacrificial layer 132 may be different from the height h7 of the second sacrificial layer 136, both the first sacrificial layer 132 and the second sacrificial layer 136 are not filled with the gate electrode 170, but may be formed with a sufficiently thin thickness so that air gaps 152 and 154 are formed thereon. That is, if the thickness h5 or h7 of the first or second sacrificial layer 132 or 136 is smaller than the gap-fill limit value of the gate electrode 170, the gate electrode 170 does not fill in a space that is formed through etching of the sacrificial layers 132 and 136 on the lower portions of the active layers 134 and 138, and thus the air gaps 152 and 154 are formed therein. For example, the first or second sacrificial layer 132 or 136 may be formed with a thickness of 2 to 4 nm. However, the present inventive concept is not limited thereto.

The air gaps 152 and 154 may include the first air gap 152 and the second air gap 154. The first air gap 152 may be positioned between the first active layer 134 and the substrate 100. The second air gap 154 may be positioned between the first active layer 134 and the second active layer 138. The height h4 of the first air gap 152 may be lower than the height h5 of the first sacrificial layer 132. The height h6 of the second air gap 154 may be lower than the height h7 of the second sacrificial layer 136.

The first and second air gaps 152 and 154 may be positioned on the lower portions of the first and second active layers 134 and 138 to overlap the first and second active layers.

The gate insulating layer 160 may be formed to completely surround the first and second active layers 134 and 138. Further, as illustrated, the gate insulating layer 160 may he formed to extend upward along the side wall of a spacer 175. Further, the gate insulating layer 160 may be formed to completely surround the circumferences of the first and second air gaps 152 and 154.

The gate electrode 170 may be formed on the gate insulating layer 160. As illustrated, the gate electrode 170 may be formed to surround parts of the first and second active layers 134 and 138. Specifically, the gate electrode 170 may surround only the side surface of the first active layer 134 and the upper surface and both side surfaces of the second active layer 138. That is, the gate electrode 170 need not be formed on the lower portions of the first and second active layers 134 and 138. The first and second air gaps 152 and 154 may be formed on the lower portions of the active layers 134 and 138 that are not filled with the gate electrode 170. The gate electrode 170 may be convexly formed on the parts of the lower portions of the active layers 134 and 138, but the present inventive concept is not limited thereto.

In the case where the plurality of active layers 134 and 138 are provided, a plurality of nanowires may be formed to improve the operation characteristics of the second transistor TR2.

Since other constituent elements may be the same as those as described above, the duplicate explanation thereof may be omitted.

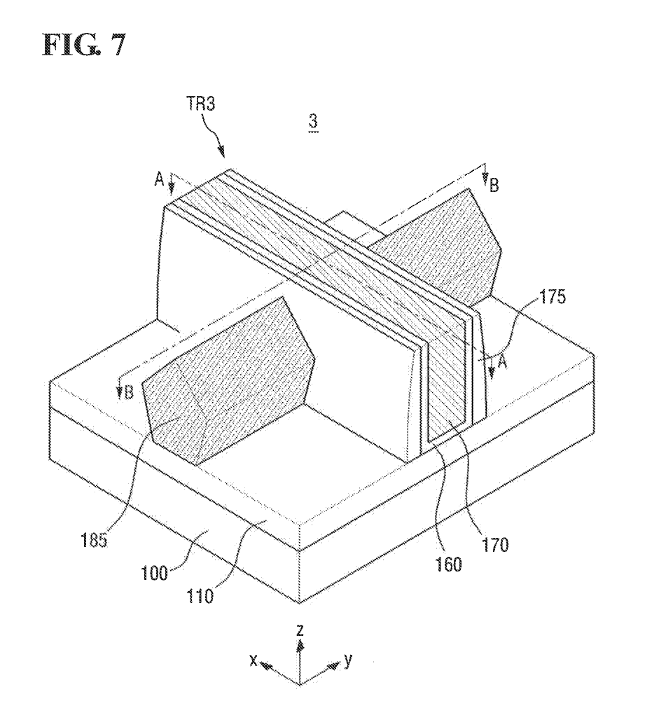

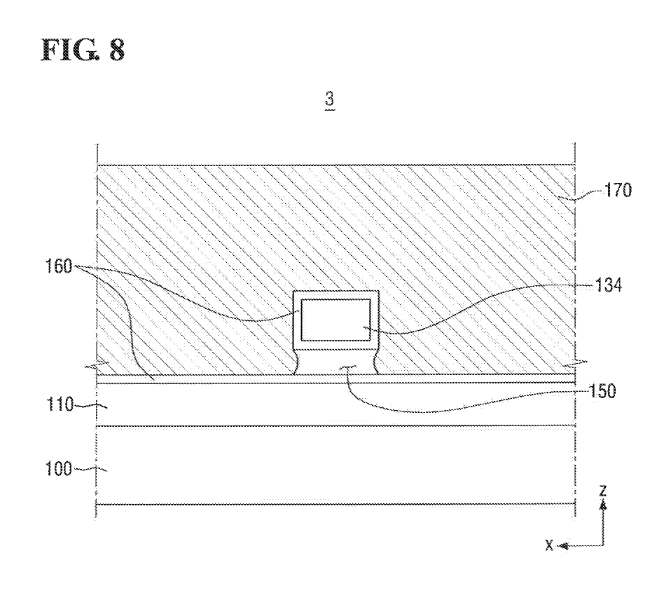

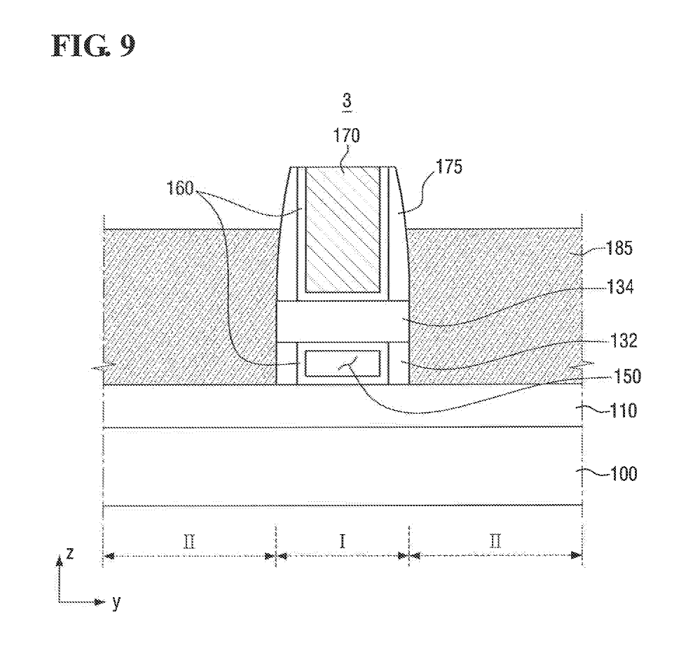

FIG. 7 is a perspective view illustrating a semiconductor device according to an exemplary embodiment of the present inventive concept. FIG. 8 is a cross-sectional view taken along line A-A of FIG. 7, and FIG. 9 is a cross-sectional view taken along line B-B of FIG. 7.

Hereinafter, a semiconductor device 3 according to an exemplary embodiment of the present inventive concept will be described, and a third transistor TR3 including an air gap 150 will be described. However, the present inventive concept is not limited to a particular embodiment.

Referring to FIGS. 7 to 9, unlike the semiconductor device 1 as described above, a semiconductor device 3 according to an exemplary embodiment does not include parts of the sacrificial layer 132 and the active layer 134 that do not overlap the gate electrode 170, the gate insulating layer 160, or the spacer 175.

Specifically, if it is assumed that a region of the sacrificial layer 132 and the active layer 134, which overlaps the gate electrode 170, the gate insulating layer 160, or the spacer 175, is a first region and the remaining region is a second region, the sacrificial layer 132 and the active layer 134 need not exist in the second region. Accordingly, the sacrificial layer 132 and the active layer 134 need not exist on the lower portion of the source/drain 185. That is, the lower surface of the source/drain 185 may be disposed to be lower than the lower surface of the active layer 134, and the active layer 134 need not be disposed on the lower portion of the source/drain 185. However, the present inventive concept is not limited thereto.

The source/drain 185 may be formed on both sides of the gate electrode 170. The source/drain 185 may come in contact with the upper surface of the isolation layer 110 and the side surface of the spacer 175. Further, the source/drain 185 may be connected to the active layer 134 and the sacrificial layer 132. In an exemplary embodiment, the source/drain 185 may be formed, for example, through an epitaxial growth process. During the epitaxial process, although not clearly illustrated in the drawing, a seed layer for the epitaxial growth may be formed on the lower portion of the source/drain 185. Further, if desired, during the epitaxial process, impurities may be in-situ doped.

The source/drain 185 is exemplarily illustrated to be in a pentagonal shape, but is not limited thereto. That is, through adjustment of the processing conditions of the epitaxial process to form the source/drain 185, the source/drain 185 may be in various shapes, such as a diamond shape, a rectangular shape, and a hexagonal shape.

The sacrificial layer 132 that is connected to the source/drain 185 may be positioned only on the lower portion of the spacer 175 to overlap the spacer 175. The active layer 134 that connects to the source/drain 185 may be used as a channel of the third transistor TR3. That is, the active layer 134 may function as a nanowire.

Since other constituent elements may be the same as those as described above, the duplicate explanation thereof may be omitted.

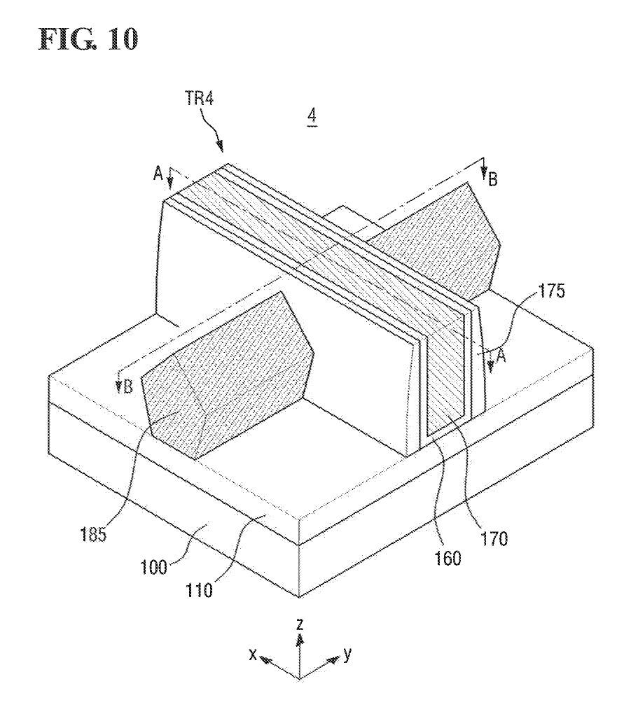

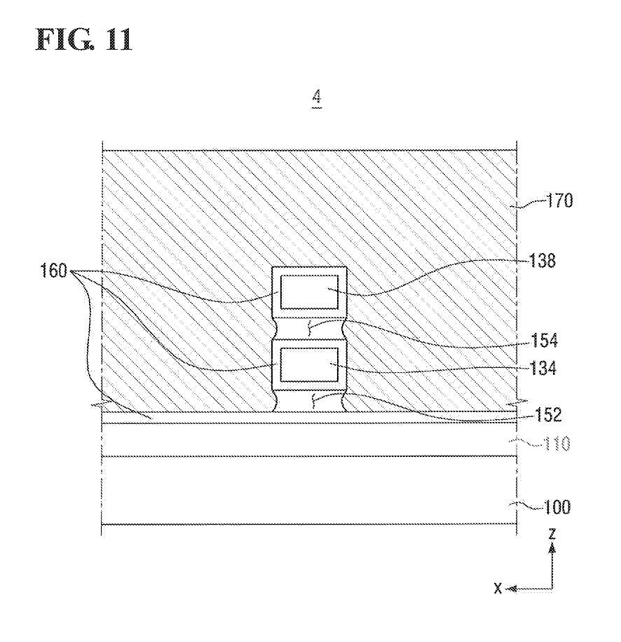

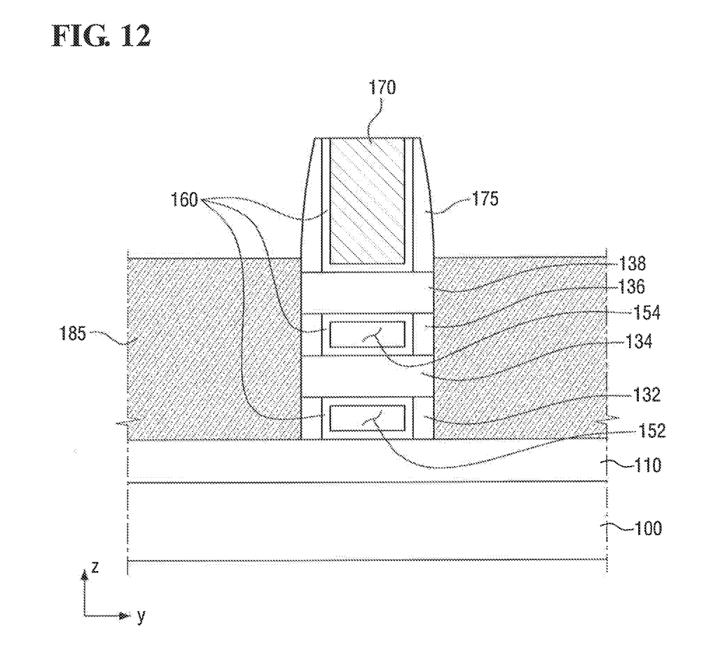

FIG. 10 is a perspective view illustrating a semiconductor device according to an exemplary embodiment of the present inventive concept. FIG. 11 is a cross-sectional view taken along line A-A of FIG. 10, and FIG. 12 is a cross-sectional view taken along line B-B of FIG. 10.

Hereinafter, a semiconductor device 4 according to an exemplary embodiment of the present inventive concept will be described, and a fourth transistor TR4 including an air gap 150 will be described. However, the present inventive concept is not limited to a particular embodiment.

Referring to FIGS. 10 to 12, unlike the semiconductor device 3 as described above, a semiconductor device 4 according to an exemplary embodiment may include a plurality of sacrificial layers 132 and 136 and a plurality of active layers 134 and 138.

Specifically, a structure, in which the sacrificial layers 132 and 136 and the active layers 134 and 138 are repeated to be alternately laminated, may be formed on the substrate 100. The active layers 134 and 138 are made of Si, and the sacrificial layers 132 and 136 are made of SiGe, but are not limited thereto. The number of repetitions the active layers 134 and 138 and the sacrificial layers 132 and 136 are alternately laminated may differ depending on the number of nanowires to be formed thereafter. The semiconductor device 4 according to an exemplary embodiment includes two sacrificial layers 132 and 136 and two active layers 134 and 138. However, the present inventive concept is not limited thereto, and the semiconductor device 4 according to an exemplary embodiment may include three or more active layers or sacrificial layers.

The sacrificial layers 132 and 136 may include the first sacrificial layer 132 and the second sacrificial layer 136. The second sacrificial layer 136 may be positioned on the first sacrificial layer 132.

The active layers 134 and 138 may include the first active layer 134 and the second active layer 138. The first active layer 134 may be positioned between the first sacrificial layer 132 and the second sacrificial layer 136, and the second active layer 138 may be positioned on the second sacrificial layer 136. That is, the first sacrificial layer 132, the first active layer 134, the second sacrificial layer 136, and the second active layer 138 may be formed in order on the substrate.

The air gaps 152 and 154 may include the first air gap 152 and the second air gap 154. The first air gap 152 may be positioned between the first active layer 134 and the substrate 100. The second air gap 154 may he positioned between the first active layer 134 and the second active layer 138.

The first and second air gaps 152 and 154 may he positioned on the lower portions of the first and second active layers 134 and 138 to overlap the first and second active layers 134 and 138.

The gate insulating layer 160 may be formed to completely surround the first and second active layers 134 and 138. Further, as illustrated, the gate insulating layer 160 may be formed to extend upward along the side wall of a spacer 175. Further, the gate insulating layer 160 may be formed to completely surround the circumferences of the first and second air gaps 152 and 154.

The gate electrode 170 may be formed on the gate insulating layer 160. As illustrated, the gate electrode 170 may be formed to surround parts of the first and second active layers 134 and 138. Specifically, the gate electrode 170 may surround only the side surface of the first active layer 134 and the upper surface and both side surfaces of the second active layer 138. That is, the gate electrode 170 need not be formed on the lower portions of the first and second active layers 134 and 138. The first and second air gaps 152 and 154 may be formed on the lower portions of the active layers 134 and 138 that are not filled with the gate electrode 170. The gate electrode 170 may be convexly formed on the parts of the lower portions of the active layers 134 and 138, but the present inventive concept is not limited thereto.

The first and second sacrificial layers 132 and 136 connected to the source/drain 185 may be positioned only on the lower portion of the spacer 175 to overlap the spacer 175. The first and second active layer 134 and 138 that connect to the source/drain 185 may be used as a channel of the fourth transistor TR4. That is, the first and second active layers 134 and 138 may function as nanowires.

In the case where a plurality of nanowires are provided, the operation characteristics of the fourth transistor TR4 can be improved due to the increase of the number of channels. Further, in the case where the plurality of air gaps 152 and 154 are provided, unwanted capacitance that is generated in the fourth transistor TR4 can be reduced. Further, the channel stress that is applied to the active layers 134 and 138 can be reduced.

Since other constituent elements may be the same as those as described above, the duplicate explanation thereof may be omitted.

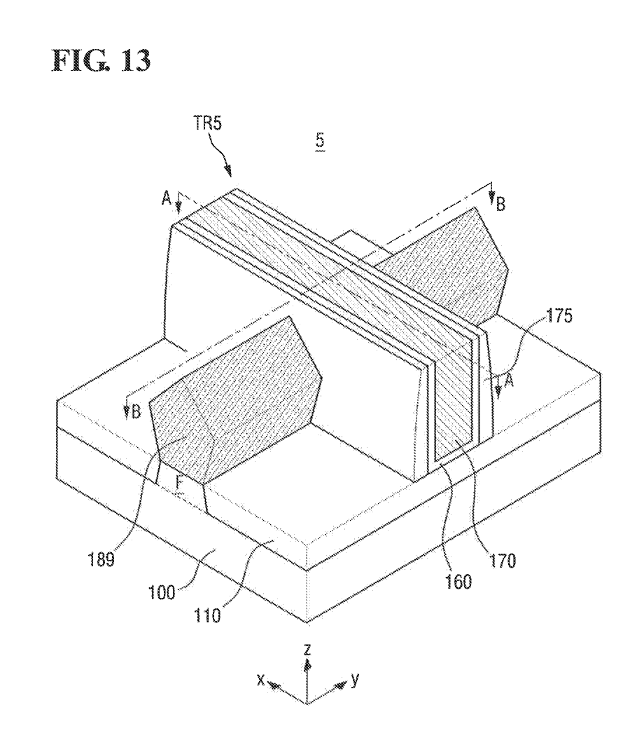

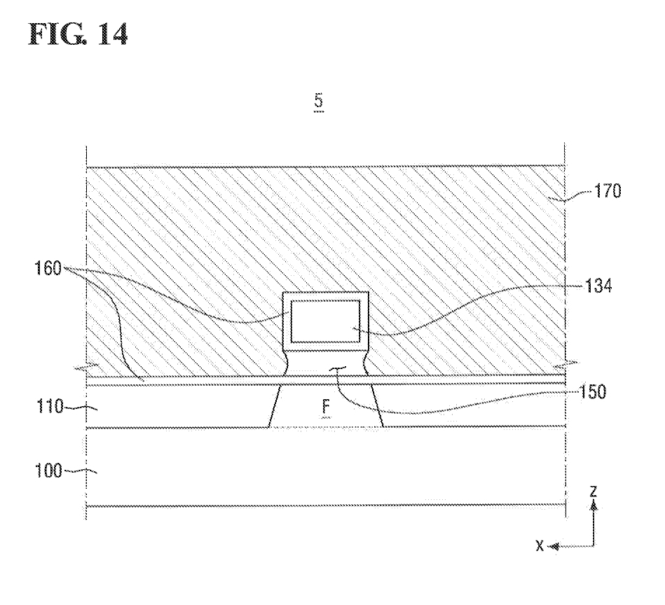

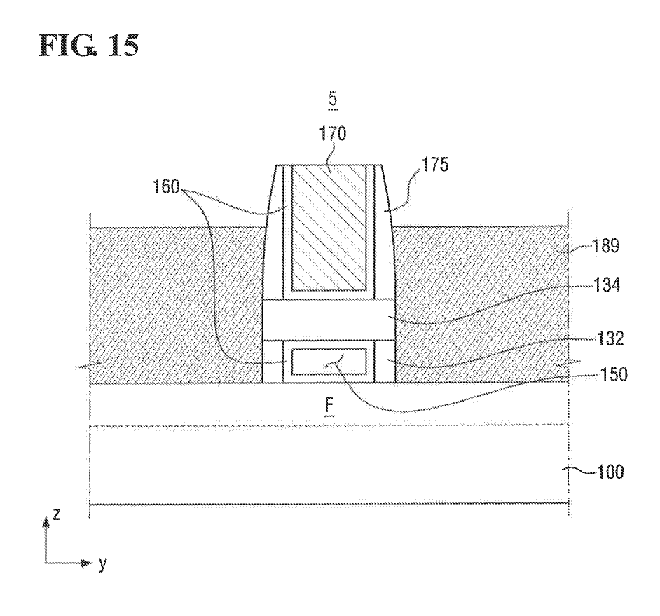

FIG. 13 is a perspective view illustrating a semiconductor device according to an exemplary embodiment of the present inventive concept. FIG. 14 is a cross-sectional view taken along line A-A of FIG. 13, and FIG. 15 is a cross-sectional view taken along line B-B of FIG. 13.

Hereinafter, a semiconductor device 5 according to an exemplary embodiment of the present inventive concept will be described, and a fifth transistor TR5 including an air gap 150 will be described. However, the present inventive concept is not limited to a particular embodiment.

Referring to FIGS. 13 to 15, unlike the semiconductor device 3 as described above, a semiconductor device 5 according to an exemplary embodiment may include a fin F.

The fin F may be disposed on the substrate 100. In some embodiments of the present inventive concept, the fin F may include the same material as the material of the substrate. For example, if the substrate 100 includes silicon, the fin F may also include silicon. On the other hand, the present inventive concept is not limited thereto, and if desired, various modifications may be made without limits. For example, in some embodiments of the present inventive concept, the substrate 100 and the fin F may include different materials.

The fin F may be formed to project from the substrate 100. In some embodiments of the present inventive concept, the fin F may be formed through etching of a part of the substrate 100, but the present inventive concept is not limited thereto.

In the drawing, it is illustrated that the cross section of the fin F is tapered so that the width of the fin F becomes wider as going from the upper portion to the lower portion. However, the present inventive concept is not limited thereto. In some embodiments of the present inventive concept, the cross section of the fin F may be modified in a rectangular shape. Further, in some other embodiments of the present inventive concept, the cross section of the fin F may be in a chamfered shape. That is, the corner portion of the fin F may be rounded.

An active fin F may be formed using an epitaxial layer that is formed on the base substrate 100. In this case, the epitaxial layer may include silicon or germanium. Further, the epitaxial layer may include a compound semiconductor, and for example, may include group IV-IV compound semiconductor or group III-V compound semiconductor. Specifically, according to an example of the group IV-IV compound semiconductor, the epitaxial layer may include a binary compound including at least two of carbon (C), silicon (Si), germanium (Ge), and tin (Sn), a ternary compound, or a compound including the above-described elements doped with group IV elements. According to an example of the group III-V compound semiconductor, the epitaxial layer may include a binary compound formed through combination of at least one of group III elements, such as aluminum (Al), gallium (Ga), and indium (In), and one of group V elements, such as phosphorus (P), arsenide (As), and antimonium (Sb), a ternary compound, or a quaternary compound.

The isolation layer 110 may cover the side surface of the fin F. In some embodiments of the present inventive concept, the isolation layer 110 may be, for example, an insulating layer. More specifically, the isolation layer 110 may be, for example, a silicon oxide (SiO2) layer, a silicon nitride (SiN) layer, or a silicon oxynitride (SiON) layer, but the present inventive concept is not limited thereto.

In some embodiments of the present inventive concept, the isolation layer 110 may be, for example, a STI (Shallow Trench Isolation) layer. However, the present inventive concept is not limited thereto. In some embodiments of the present inventive concept, the isolation layer 110 may be a DTI (Deep Trench Isolation) layer. That is, the isolation layer 110 according to embodiments of the present inventive concept is not limited to a particular embodiment.

The sacrificial layer 132 and the active layer 134 may be formed on the fin F. Further, the source/drain 189 may be formed on the fin F. The air gap 150 may overlap the fin F.

In the case where the fifth transistor TR5 is a PMOS transistor, the source/drain 189 may include a compression stress material. The compression stress material may be a material having higher lattice constant than Si, and for example, may be SiGe. The compression stress material may improve mobility of carriers of a channel region by applying compression stress to the fin F.

In the case where the fifth transistor TR5 is an NMOS transistor, the source/drain 189 may include the same material as the substrate 100 or a tensile stress material. For example, if the substrate 100 includes Si, the source/drain 189 may include Si or a material (e.g., SiC) having lower lattice constant than Si.

The source/drain 189 may be formed through an epitaxial process. Further, if desired, impurities may be in-situ doped during the epitaxial process.

The source/drain 189 is exemplarily illustrated to be in a hexagonal shape, but is not limited thereto. That is, through adjustment of the processing conditions of the epitaxial process to form the source/drain 189, the source/drain 189 may be in various shapes, such as a diamond shape, a rectangular shape, and a pentagonal shape.

Since other constituent elements may be the same as those as described above, the duplicate explanation thereof may be omitted.

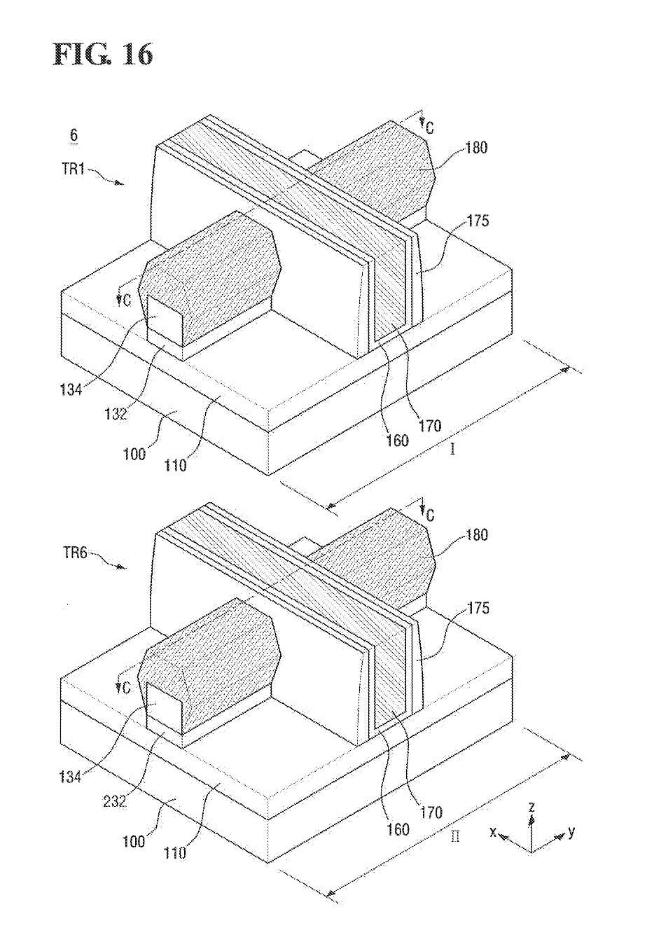

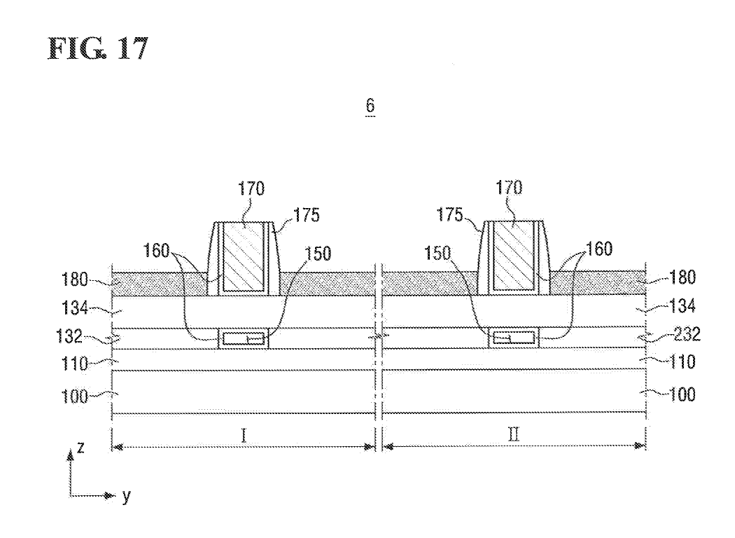

FIG. 16 is a perspective view illustrating a semiconductor device according to an exemplary embodiment of the present inventive concept, and FIG. 17 is a cross-sectional view taken along line C-C of FIG. 16.

Referring to FIGS. 16 and 17, the substrate 100 of a semiconductor device 6 may include a first region I and a second region II. The first P-type transistor TR1 may be formed on the first region I, and the second N-type transistor TR6 may be formed on the second region II. The first transistor TR1 and the second transistor TR6 may be formed substantially in the same manner.

The sacrificial layer 132 formed on the first region I and the sacrificial layer 232 formed on the second region II may include different materials. Specifically, for example, the sacrificial layer 132 may include a semiconductor material, and the sacrificial layer 232 may include an insulating layer. More specifically, the sacrificial layer 132 may include silicon germanium (SiGe), and the sacrificial layer 232 may include oxide. If the sacrificial layer 125 formed on the lower portion of the source/drain 180 is an oxide layer, the stress is not applied to the active layer 134. Accordingly, the operation characteristics of the second transistor TR6 that is an NMOS transistor need not deteriorate.

As described above, if the sacrificial layers 132 and 232 that are respectively formed on the first region I and the second region II are different from each other, the operation characteristics of the first P-type transistor TR1 and the second N-type transistor TR6 can be improved.

Further, in some embodiments of the present inventive concept, both the sacrificial layers 132 and 232 formed on the first region I and the second region II may include silicon germanium (SiGe), but the concentrations of germanium (Ge) included in the respective sacrificial layers 132 and 232 may be different from each other. Accordingly, the operation characteristics of the first P-type transistor TR1 and the second N-type transistor TR6 can be improved.

Since other constituent elements may be the same as those as described above, the duplicate explanation thereof may be omitted.

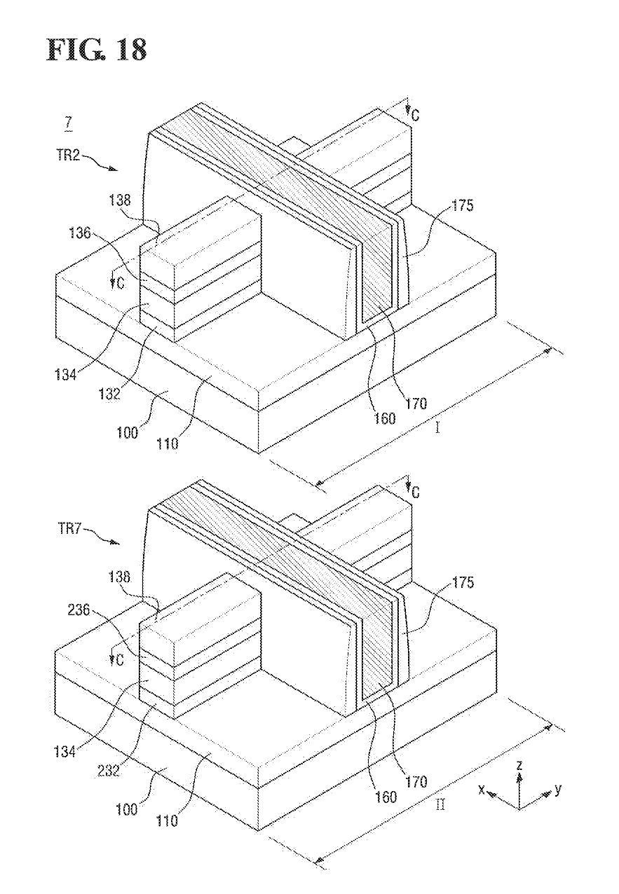

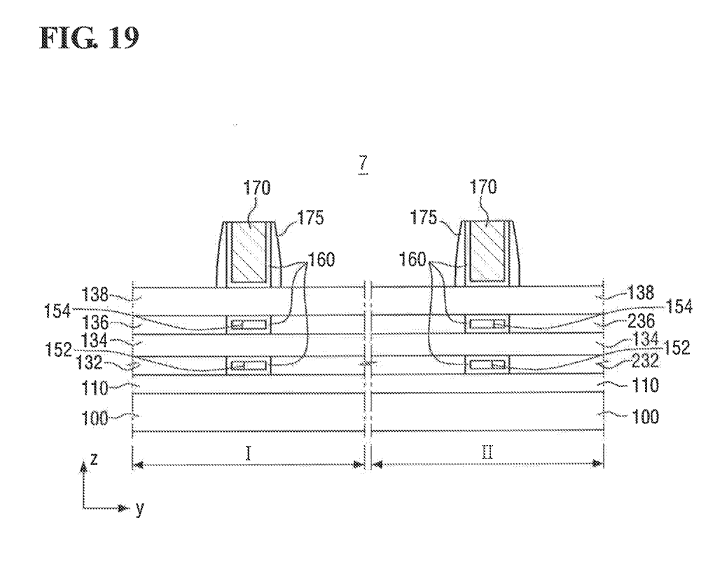

FIG. 18 is a perspective view illustrating a semiconductor device according to an exemplary embodiment of the present inventive concept, and FIG. 19 is a cross-sectional view taken along line C-C of FIG. 16.

Referring to FIGS. 18 and 19, the substrate 100 of a semiconductor device 7 may include a first region I and a second region II. The third P-type transistor TR2 may be formed on the first region I, and the fourth N-type transistor TR7 may be formed on the second region II. The third transistor TR2 and the fourth transistor TR7 may be formed substantially in the same manner.

In this case, the first and second sacrificial layers 132 and 134 formed on the first region I and the third and fourth sacrificial layers 232 and 234 formed on the second region II may include different materials. Specifically, for example, the first and second sacrificial layers 132 and 134 may include a semiconductor material, and the third and fourth sacrificial layers 232 and 234 may include an insulating layer. More specifically, for example, the first and second sacrificial layers 132 and 134 may include silicon germanium (SiGe), and the third and fourth sacrificial layers 232 and 234 may include oxide. If the third and fourth sacrificial layers 232 and 234 are made of oxide, the stress is not applied to the plurality of active layers 134 and 138. Accordingly, the operation characteristics of the fourth transistor TR7 that is an NMOS transistor need not deteriorate.

As described above, if the first and second sacrificial layers 132 and 134 that are formed on the first region I and the third and fourth sacrificial layers 232 and 234 that are formed on the second region II are different from each other, the operation characteristics of the third P-type transistor TR2 and the fourth N-type transistor can be improved.

Further, in some embodiments of the present inventive concept, all the sacrificial layers 132, 134, 232, and 234 formed on the first region I and the second region II may include silicon germanium (SiGe), but the concentrations of germanium (Ge) included in the sacrificial layers 132 and 134 of the first region and the sacrificial layers 232 and 234 of the second region may be different from each other. Accordingly, the operation characteristics of the third P-type transistor TR2 and the fourth N-type transistor TR7 can be improved.

Since other constituent elements may be the same as those as described above, the duplicate explanation thereof may be omitted.

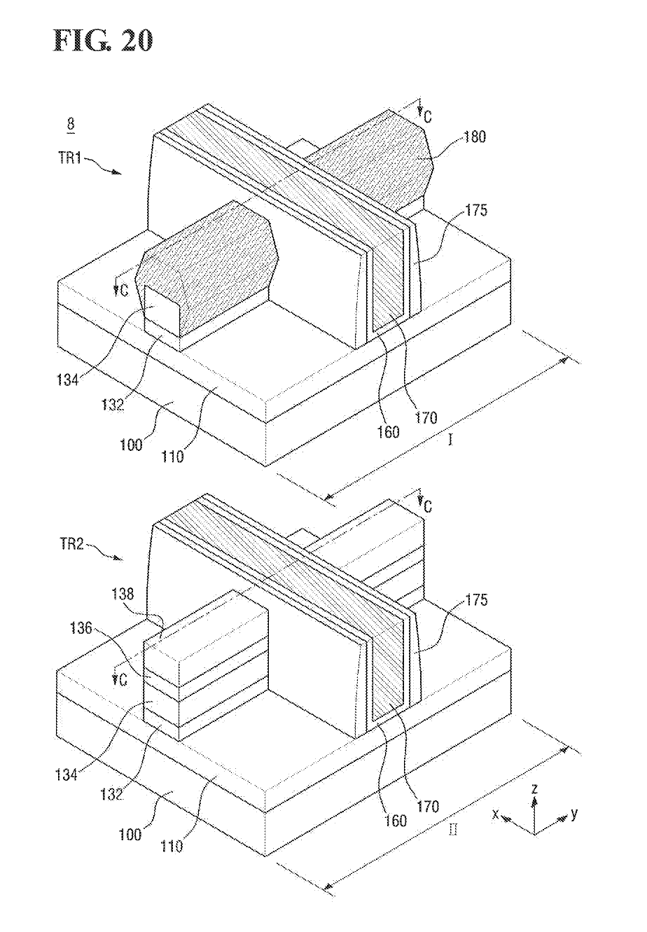

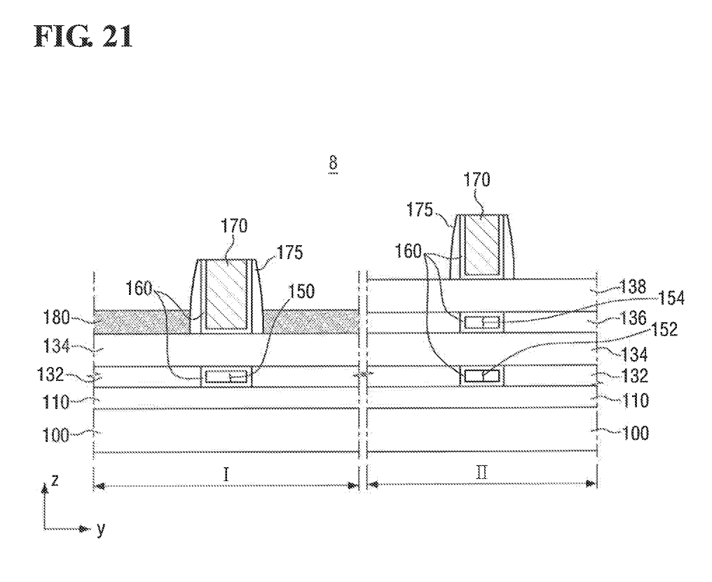

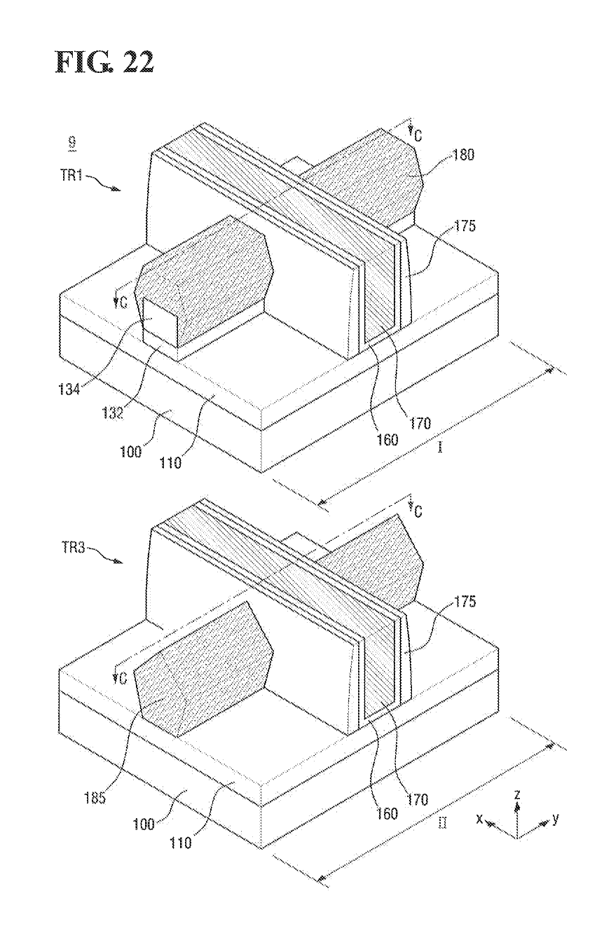

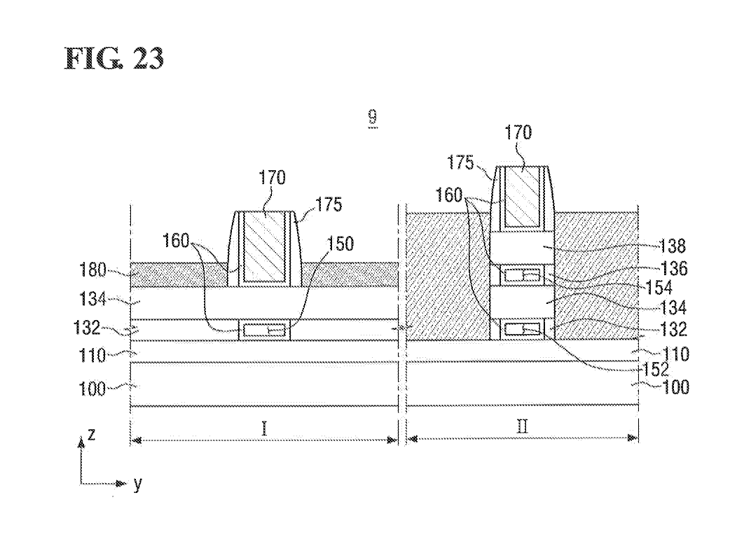

FIG. 20 is a perspective view illustrating a semiconductor device according to an exemplary embodiment of the present inventive concept, and FIG. 21 is a cross-sectional view taken along line C-C of FIG. 16. FIG. 22 is a perspective view illustrating a semiconductor device according to an exemplary embodiment of the present inventive concept, and FIG. 23 is a cross-sectional view taken along line C-C of FIG. 16.

Referring to FIGS. 20 and 21, different transistors TR1 and TR2 may be formed on the first region I and the second region II of a semiconductor device 8.

Specifically, the first transistor TR1 as described above may be formed on the first region I of the substrate 100, and the second transistor TR2 that is different from the first transistor TR1 may be formed on the second region II of the substrate 100.

As illustrated, the first transistor TR1 may include one sacrificial layer 132, one active layer 134, and one air gap 150, and the second transistor TR2 may include a plurality of sacrificial layers 132 and 136, a plurality of active layers 134 and 138, and a plurality of air gaps 152 and 154. In other words, the first transistor TR1 may have one air gap 150 and one active layer 134, and the second transistor TR2 may have a plurality of air gaps 152 and 154 and a plurality of active layers 134 and 138. For example, the second transistor TR2 may have two air gaps 152 and 154 and two active layers 134 and 138. Accordingly, unwanted capacitance in the second transistor TR2 can be reduced, and the number of nanowires can be increased. However, the present inventive concept is not limited thereto.

In some embodiments of the present inventive concept, the first transistor TR1 and the second transistor TR2 may have the same conduction type. Specifically, for example, both the first transistor TR1 and the second transistor TR2 may be PMOS transistors, but the present inventive concept is not limited thereto.

On the other hand, FIGS. 20 and 21 illustrate that the first transistor TR1 is formed on the first region I of the substrate 100. However, the present inventive concept is not limited thereto, and if desired, modifications may be made without limits.

For example, referring to FIGS. 22 and 23, in some embodiments of the present inventive concept, the first transistor TR1 (in FIG. 1) as described above may be formed on the first region I of the substrate 100, and the third transistor TR3 (in FIG. 7) may be formed on the second region II of the substrate 100.

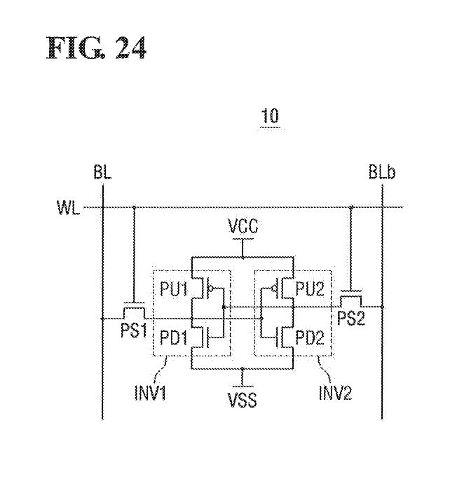

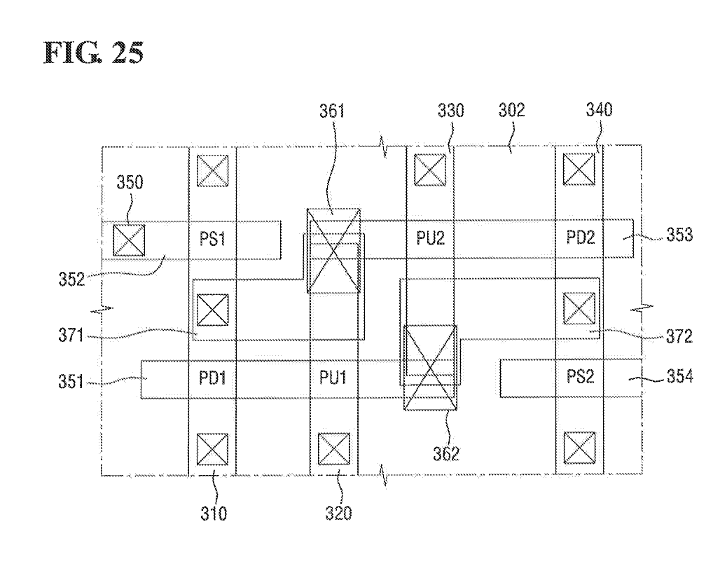

FIG. 24 is a circuit diagram explaining a semiconductor device according to some embodiments of the present inventive concept, and FIG. 25 is a layout diagram of a semiconductor device illustrated in FIG. 24. Hereinafter, duplicate explanation of the above-described embodiments may be omitted, and explanation will be made around different points between the some embodiments and the above-described embodiments.

Referring to FIGS. 24 and 25, a semiconductor device 10 may include a pair of inverters INV1 and INV2 connected in parallel between a power supply node Vcc and a ground node Vss, and a first path transistor PS1 and a second pass transistor PS2 connected to output nodes of the respective inverters INV1 and INV2. The first pass transistor PS1 and the second pass transistor PS2 may be connected to a bit line BL and a complementary bit line BLb. Gates of the first pass transistor PS1 and the second pass transistor PS2 may be connected to a word line WL.

The first inverter INV1 includes a first pull-up transistor PU1 and a first pull-down transistor PD1 which are connected in series, and the second inverter INV2 includes a second pull-up transistor PU2 and a second pull-down transistor PD2 which are connected in series. The first pull-up transistor PU1 and the second pull-up transistor PU2 may be PFET transistors, and the first pull-down transistor PD1 and the second pull-down transistor PD2 may be NFET transistors.

Further, the first inverter INV1 and the second inverter INV2 may constitute one latch circuit in a manner that an input node of the first inverter INV1 is connected to an output node of the second inverter INV2, and an input node of the second inverter INV2 is connected to an output node of the first inverter INV1.

Here, referring to FIGS. 24 and 25, a first active fin 310, a second active fin 320, a third active fin 330, and a fourth active fin 340, which are spaced apart from each other, may be formed to extend in one direction (for example, upper/lower direction in FIG. 25). The extending length of the second active fin 320 and the third active fin 330 may be shorter than the extending length of the first active fin 310 and the fourth active fin 340.

Further, a first gate electrode 351, a second gate electrode 352, a third gate electrode 353, and a fourth gate electrode 354 may extend long in the other direction (for example, right/left direction in FIG. 25), and may be formed to cross the first to fourth active fins 310 to 340. Specifically, the first gate electrode 351 may be formed to completely cross the first active fin 310 and the second active fin 320 and to overlap a part of a vertical end of the third active fin 330. The third gate electrode 353 may be formed to completely cross the fourth active fin 340 and the third fin 330 and to overlap a part of a vertical end of the second active fin 320. The second gate electrode 352 and the fourth gate electrode 354 may be formed to cross the first active fin 310 and the fourth active fin 340, respectively.

As illustrated, the first pull-up transistor PU1 may be defined around a region where the first gate electrode 351 and the second active fin 320 cross each other, the first pull-down transistor PD1 may be defined around a region where the first gate electrode 351 and the first active fin 310 cross each other, and the first pass transistor PS1 may be defined around a region where the second gate electrode 352 and the first active fin 310 cross each other. The second pull-up transistor PU2 may be defined around a region where the third gate electrode 353 and the third active fin 330 cross each other, the second pull-down transistor PD2 may be defined around a region where the third gate electrode 353 and the fourth active fin 340 cross each other, and the second pass transistor PS2 may be defined around a region where the fourth gate electrode 354 and the fourth active fin 340 cross each other.

Although not clearly illustrated, the source/drain 180 may be formed on both sides of regions where the first to fourth gate electrodes 351 to 354 and the first to fourth active fins 310 to 340 cross each other, and a plurality of contacts 350 may be formed.

In addition, a first shared contact 361 may simultaneously connect the second active fin 320, the third gate electrode 353, and a wiring 371. A second shared contact 362 may simultaneously connect the third active fin 330, the first gate electrode 351, and a wiring 372.

The semiconductor device 10 may be used as, for example, a SRAM (Static Random Access Memory). Further, at least one transistor PU1˜2, PD1˜2, and PS1˜2 included in the semiconductor device 10 may adopt the configuration according to the above-described embodiments. For example, the first and second pull-up transistors PU1 and PU2 as illustrated in FIG. 11 may be configured by the first transistor TR1 as illustrated in FIG. 16, and the first and second pass transistors PS1 and PS2 and the first and second pull-down transistors PD1 and PD2 may be configured by the second transistor TR6 as illustrated in FIG. 16.

Further, for example, the first and second pull-up transistors PU1 and PU2 may be configured by the first transistor TR1 as illustrated in FIG. 16, and the first and second pull-down transistors PD1 and PD2 may be configured by the second transistor TR1 as illustrated in FIG. 16. The first and second pass transistors PS1 and PS2 may be configured by the third transistor TR2 as illustrated in FIG. 18.

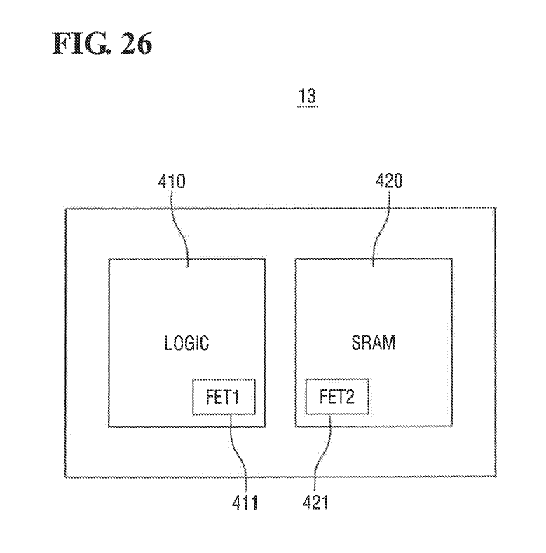

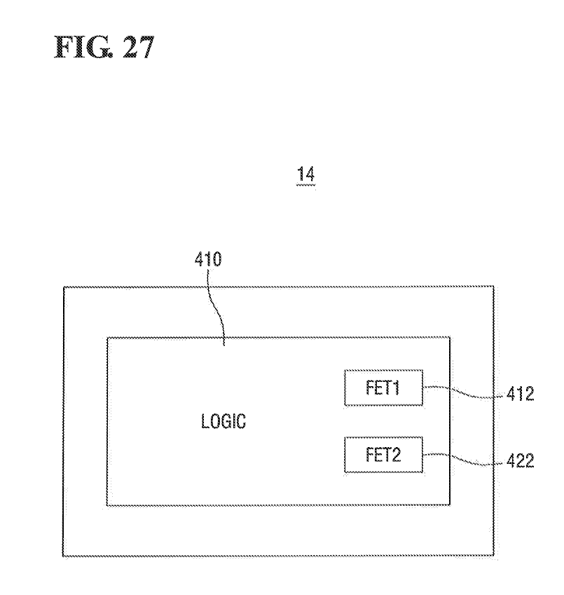

FIG. 26 is a circuit diagram illustrating a semiconductor device according to some embodiments of the present inventive concept, and FIG. 27 is a circuit diagram illustrating a semiconductor device according to exemplary embodiments of the present inventive concept. Hereinafter, duplicate explanation of the above-described embodiments may be omitted.

First, referring to FIG. 26, a semiconductor device 13 may include a logic area 410 and an SRAM formation area 420. An eleventh transistor 411 may be disposed on the logic area 410, and a twelfth transistor 421 may be disposed on the SRAM formation area 420.

In some embodiments of the present inventive concept, the eleventh transistor 411 and the twelfth transistor 421 may have different conduction types. Accordingly, if the first transistor TR1 as illustrated in FIG. 16 is adopted as the eleventh transistor 411, the second transistor TR6 as illustrated in FIG. 16 may be adopted as the twelfth transistor 421.

Further, in some embodiments of the present inventive concept, the eleventh transistor 411 and the twelfth transistor 421 may have the same conduction type. Accordingly, if the first transistor TR1 as illustrated in FIG. 18 is adopted as the eleventh transistor 411, the third transistor TR7 as illustrated in FIG. 18 may be adopted as the twelfth transistor 421.

Next, referring to FIG. 27, a semiconductor device 14 may include a logic area 410, and thirteenth and fourteenth transistors 412 and 422, which are different from each other, may be disposed in the logic area 410. On the other hand, although not separately illustrated, the thirteenth and fourteenth transistors 412 and 422, which are different from each other, may be disposed even in the SRAM region.

In some embodiments of the present inventive concept, the thirteenth and fourteenth transistors 412 and 422 may have different conduction types. Accordingly, if the first transistor TR1 as illustrated in FIG. 16 is adopted as the thirteenth transistor 412, the second transistor TR6 as illustrated in FIG. 16 may be adopted as the fourteenth transistor 422.

Further, in some other embodiments of the present inventive concept, the thirteenth and fourteenth transistors 412 and 422 may have the same conduction type. Accordingly, if the first transistor TR2 as illustrated in FIG. 18 is adopted as the thirteenth transistor 412, the third transistor TR7 as illustrated in FIG. 18 may be adopted as the fourteenth transistor 422.

On the other hand, FIG. 27 exemplarily illustrates the logic area 410 and the SRAM area 420, but the present inventive concept is not limited thereto. For example, the present inventive concept can be applied even to the logic area 410 and other regions where memories are formed (e.g., DRAM, MRAM, RRAM, and PRAM).

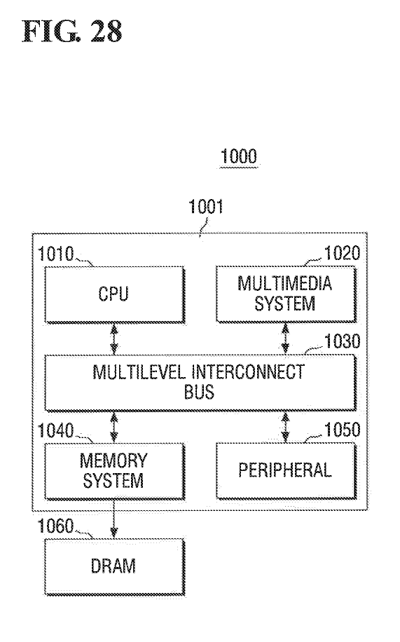

FIG. 28 is a block diagram of a SoC system that includes a semiconductor device according to embodiments of the present inventive concept.

Referring to FIG. 28, a SoC system 1000 includes an application processor 1001 and a DRAM 1060.

The application processor 1001 may include a central processing unit 1010, a multimedia system 1020, a bus 1030, a memory system 1040, and a peripheral circuit 1050.

The central processing unit 1010 may perform operations required to drive the SoC system 1000. In some embodiments of the present inventive concept, the central processing unit 1010 may be configured in a multi-core environment including a plurality of cores.

The multimedia system 102 may be used when the SoC system 100 performs various kinds of multimedia functions. The multimedia system 1020 may include a 3D engine module, a video codec, a display system, a camera system, and a post-processor.

The bus 1030 may be used when the central processing unit 1010, the multimedia system 1020, the memory system 1040, and the peripheral circuit 1050 perform data communication with each other. In some embodiments of the present inventive concept, examples of the bus 1030 may include a multilayer AHB (Advanced High-performance Bus) and a multilayer AXI (Advanced eXtensible Interface), but the present inventive concept is not limited thereto.

The memory system 1040 may provide an environment that is used when the application processor 1001 is connected to an external memory (e.g., DRAM 1060) to perform high-speed operation. In some embodiments of the present inventive concept, the memory system 1040 may include a separate controller (e.g., DRAM controller) for controlling the external memory (e.g., DRAM 1060).

The peripheral circuit 1050 may provide an environment that is used when the SoC system 1000 is smoothly connected to the external device (e.g., main board). Accordingly, the peripheral circuit 1050 may be provided with various interfaces for making the external device connected to the SoC system 1000 compatible.

The DRAM 1060 may function as an operating memory that is used when the application processor 1001 operates. In some embodiments of the present inventive concept, the DRAM 1060 may be disposed on an outside of the application processor 1001 as illustrated in the drawing. Specifically, the DRAM 1060 and the application processor 1001 may be packaged in the form of PoP (Package on Package).

At least one of the constituent elements of the SoC system 1000 may adopt any one of the semiconductor devices 1 to 6 and 13 to 14 according to the embodiments of the present inventive concept.

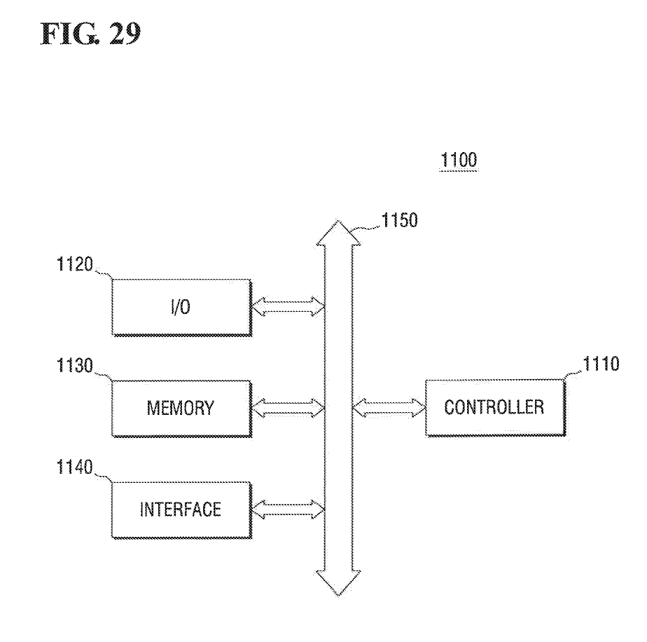

FIG. 29 is a block diagram of an electronic system that includes a semiconductor device according to embodiments of the present inventive concept.

Referring to FIG. 29, an electronic system 1100 according to an embodiment of the present inventive concept may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver.

Although not illustrated, the electronic system 1100 may further include a high-speed DRAM and/or SRAM as an operating memory for improving the operation of the controller 1110. In this case, as the operating memory, any one of the semiconductor devices 1 to 6 according to the above-described embodiments of the present inventive concept may be adopted. Further, any one of the semiconductor devices 1 to 6 according to the above-described embodiments of the present inventive concept may be provided in the memory 1130, or may be provided as a part of the controller 1110 or the I/O device 1120.

The electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

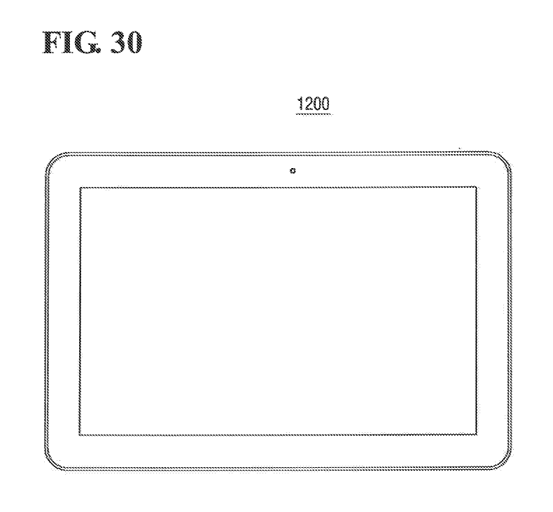

FIGS. 30 to 32 are views of exemplary semiconductor systems to which the semiconductor device according to some embodiments of the present inventive concept can be applied.

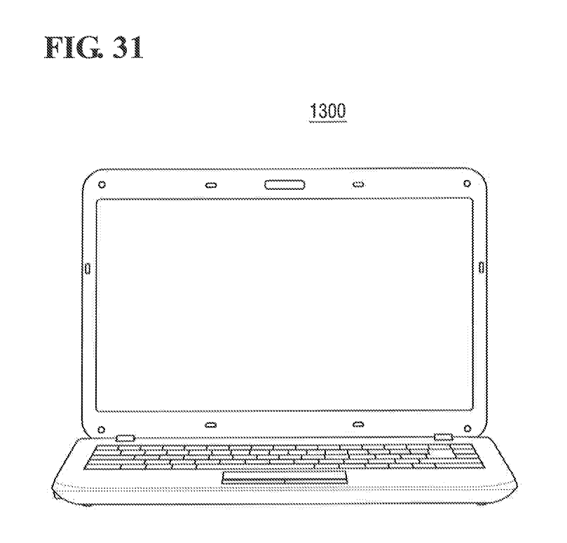

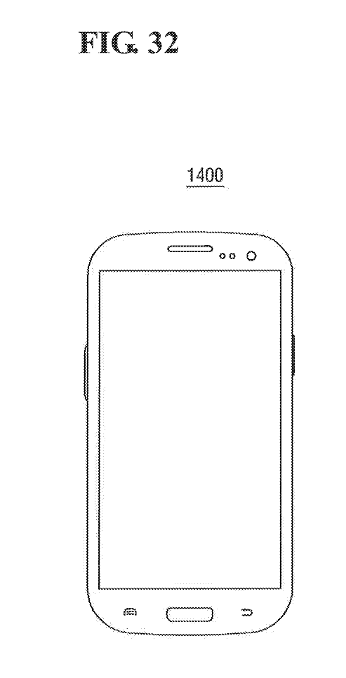

FIG. 30 illustrates a tablet PC 1200, FIG. 31 illustrates a notebook computer 1300, and FIG. 32 illustrates a smart phone 1400. At least one of the semiconductor devices 1 to 6 and 13 to 14 according to the embodiments of the present inventive concept may be used in the tablet PC 1200, the notebook computer 1300, or the smart phone 1400.

Further, it is apparent to those of skilled in the art that the semiconductor device according to some embodiments of the present inventive concept can be applied even to other integrated circuit devices that have not been exemplified. That is, although the tablet PC 1200, the notebook computer 1300, and the smart phone 1400 have been indicated as examples of the semiconductor system according to an exemplary embodiment, the examples of the semiconductor system according to an exemplary embodiment are not limited thereto. In some embodiments of the present inventive concept, the semiconductor system may be implemented as a computer, UMPC (Ultra Mobile PC), workstation, net-book, PDA (Personal Digital Assistant), portable computer, wireless phone, mobile phone, e-book, PMP (Portable Multimedia Player), portable game machine, navigation device, black box, digital camera, 3D television set, digital audio recorder, digital audio player, digital picture recorder, digital picture player, digital video recorder, or digital video player.

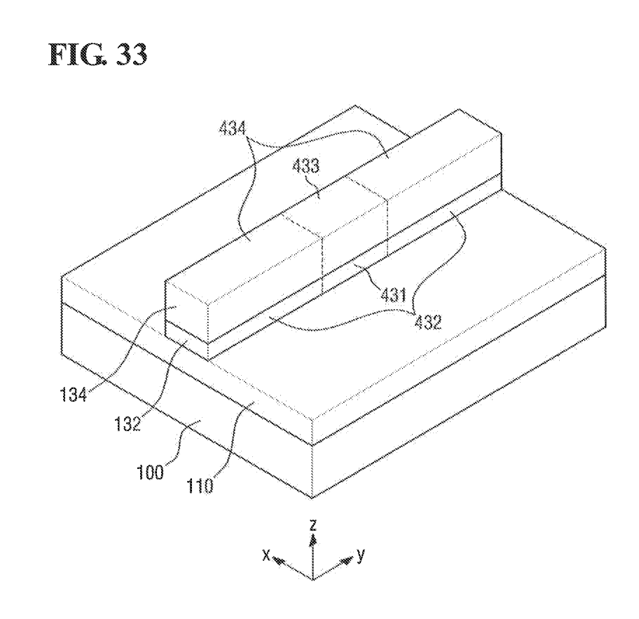

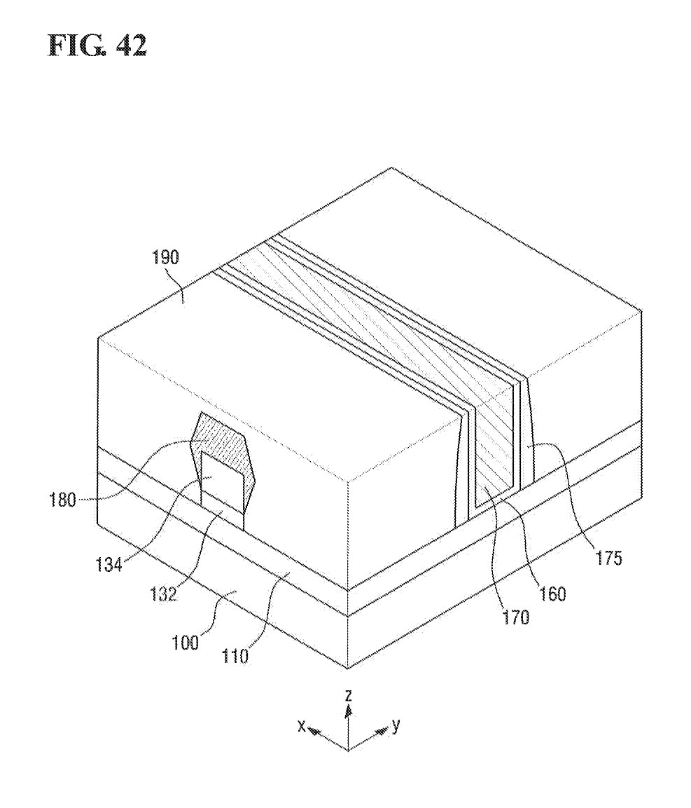

Hereinafter, referring to FIGS. 33 to 48, a method for fabricating a semiconductor device according to an embodiment of the present inventive concept will be described.

FIGS. 33 to 42 are views of intermediate steps explaining a method for fabricating a semiconductor device according to an embodiment of the present inventive concept.

First, referring to FIG. 33, an isolation layer 110 is formed on a substrate 100. Then, a first epitaxial layer is formed on the isolation layer 110 through, for example, an epitaxial growth process. Here, the first epitaxial layer may include, for example, silicon germanium (SiGe).

Then, a second epitaxial layer is formed on the first epitaxial layer through, for example, the epitaxial growth process. Here, the second epitaxial layer may include, for example, silicon (Si). Since the silicon germanium (SiGe) included in the first epitaxial layer and the silicon (Si) included in the second epitaxial layer have similar lattice structures, the second epitaxial layer can be well grown on the first epitaxial layer.

Next, the second epitaxial layer and the first epitaxial layer are sequentially etched. As the second epitaxial layer is etched, an active layer 134 may be formed as illustrated, and as the first epitaxial layer is etched, a sacrificial layer 132 may be formed as illustrated.

The active layer 134 formed as above may include a first region 433 and d second region 434. Here, a gate electrode 170 (in FIG. 1) may be formed on the upper portion of the first region 433, and the first region 433 may be used as a channel of the transistor TR1 (in FIG. 1). A source/drain 180 (in FIG. 1) may be formed on the upper portion of the second region 434.

Further, the sacrificial layer 132 may also include the first region 431 and the second region 432. Here, the first region 431 may be a region that is removed so that an air gap 150 (see e.g., FIG. 2) is formed therein, and the second region 432 may be a region that provides a stress that is used by the channel of the transistor TR1 (in FIG. 1). The active layer 134 and the sacrificial layer 132 overlap each other, and may extend in a second direction (e.g., y-axis direction).

On the other hand, in the present inventive concept, the forming of the sacrificial layer 132 and the active layer 134 is not limited thereto. In some embodiments of the present inventive concept, the sacrificial layer 132 and the active layer 134 may be formed in different methods.

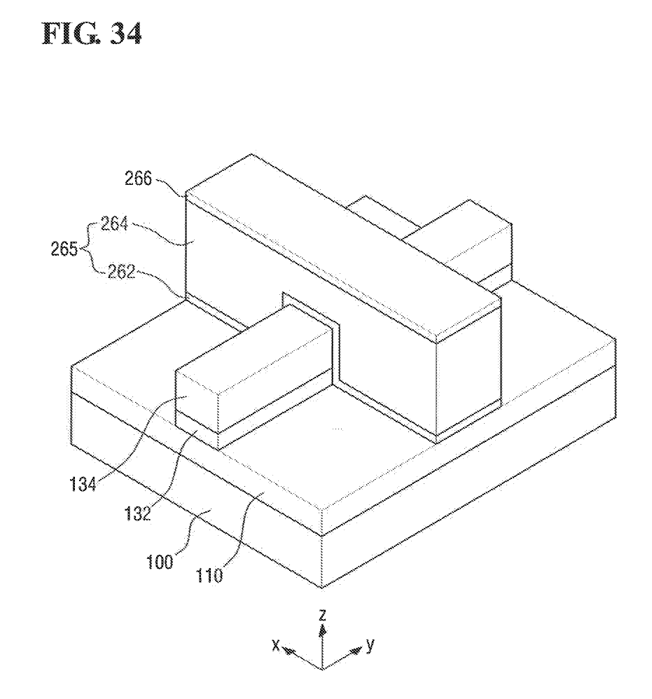

Next, referring to FIG. 34, a dummy gate pattern 265 that crosses the active layer 134 and extends in the first direction (x-axis direction) may be formed through performing of an etching process using a mask pattern 266.

Through this, the dummy gate pattern 265 is formed on the active layer 134. The dummy gate pattern 265 may overlap a part of the active layer 134. The active layer 134 includes a portion that is covered by the dummy gate pattern 265 (first region 433 (in FIG. 33) of the active layer 134) and a portion that is exposed by the dummy gate pattern 265 (second region 43 (in FIG. 34) of the active layer 134).

The dummy gate pattern 265 includes a dummy gate insulating layer 262 and a dummy gate electrode 264. For example, the dummy gate insulating layer 262 may be a silicon oxide layer, and the dummy gate electrode 264 may include poly silicon (poly-Si).

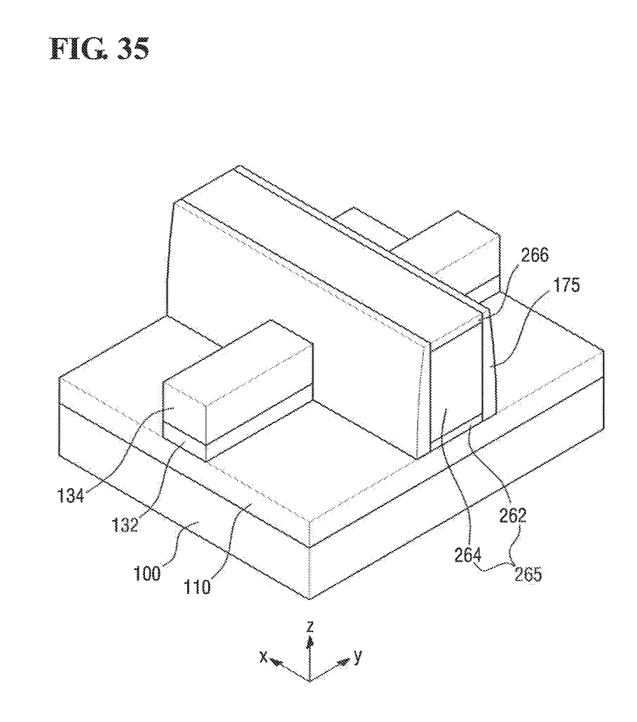

Then, referring to FIG. 35, a spacer 175 is formed on both sides of the dummy gate pattern 265. The spacer 175 may be formed by forming at least one of a silicon nitride layer and a silicon oxynitride layer on the active layer 134 and etching the formed layer, but the present inventive concept is not limited thereto.

Specifically, the spacer 175 may be formed through performing of an etch-back process after an insulating layer (not illustrated) is formed on a resultant material on which the dummy gate pattern 265 is formed. The spacer 175 may expose the upper surface of the mask pattern 266 and the upper surface of the active layer 134 that does not overlap the dummy gate pattern 265.

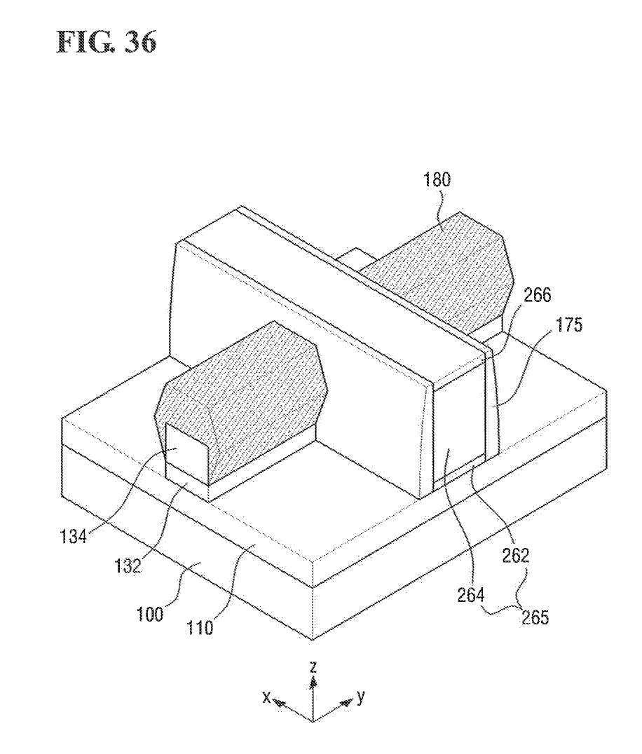

Then, referring to FIG. 36, a source/drain 180 is formed on both sides of the dummy gate pattern 265. In some embodiments of the present inventive concept, the source/drain 180 may be formed on both sides of the dummy gate pattern 265 using, for example, an epitaxial growth process. In some embodiments of the present inventive concept, the source/drain 180 may be formed to be higher than the sacrificial layer 132 as illustrated. However, the present inventive concept is not limited thereto.

The source/drain 180 is exemplarily illustrated to be in a hexagonal shape, but is not limited thereto. That is, through the adjustment of the processing conditions of the epitaxial process to form the source/drain 180, the source/drain 180 may be in various shapes, such as a diamond shape, a rectangular shape, and a pentagonal shape.

FIG. 36 illustrates that the source/drain 180 is formed through the epitaxial growth process, but the present inventive concept is not limited thereto. In some embodiments of the present inventive concept, the source/drain 180 may be formed inside the active layer 134 that is disposed on both sides of the dummy gate pattern 265 through an ion implantation (IPP) process. Further, in some embodiments of the present inventive concept, although not clearly illustrated in the drawing, the source/drain 180 may be formed in a trench (not illustrated) of the active layer 134 that is disposed on both sides of the dummy gate pattern 265. Specifically, the trench (not illustrated) is formed by etching a part of the active layer 134 disposed on both sides of the dummy gate pattern 265, and the source/drain 180 may be formed inside the formed trench through, for example, the epitaxial growth process.

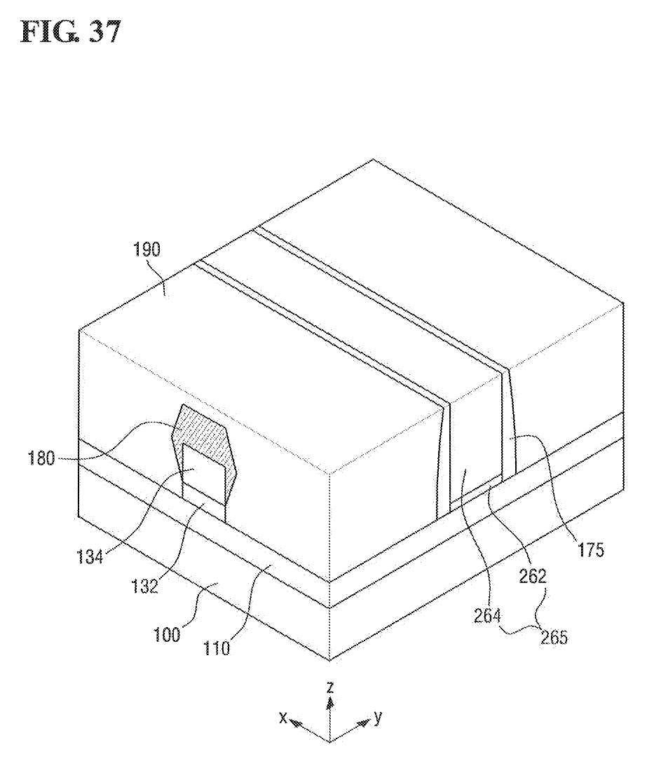

Then, referring to FIG. 37, an interlayer insulating layer 190 is formed on the resultant material on which the source/drain 180 is formed. The interlayer insulating layer 190 may include at least one of an oxide layer, a nitride layer, and an oxynitride layer. However, the present inventive concept is not limited thereto.

Then, the interlayer insulating layer 190 is planarized until the upper surface of the dummy gate pattern 265 is exposed. As a result, the mask pattern 266 is removed, and the upper surface of the dummy gate pattern 265 is exposed.

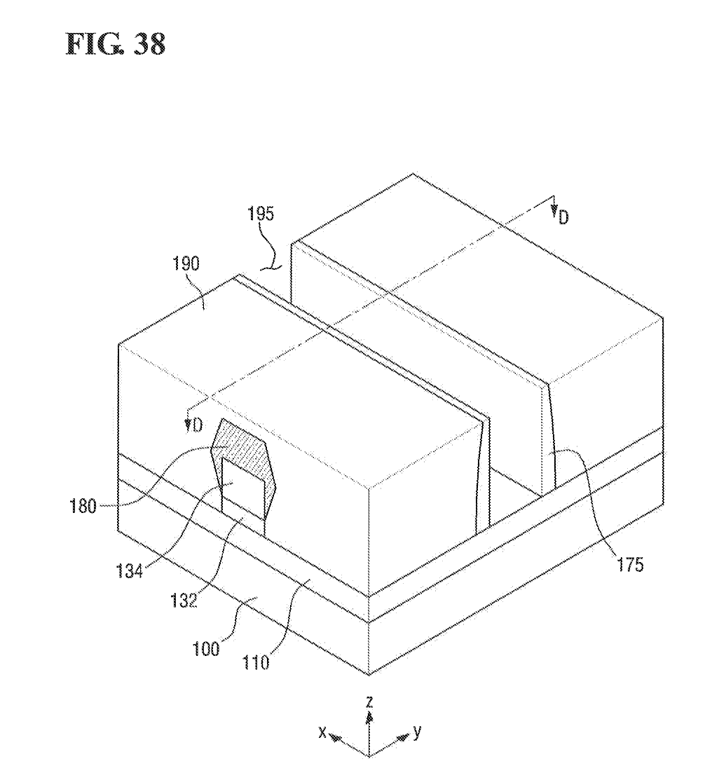

Then, referring to FIG. 38, the dummy gate pattern 265, that is, the dummy gate insulating layer 262 and the dummy gate electrode 264, may be removed. In some embodiments of the present inventive concept, first etching and second etching may be used to etch the exposed dummy gate 152, Specifically, the first etching of the exposed dummy gate pattern 265 is performed using dry etching. Then, the second etching of the residual dummy gate pattern 265 is performed using wet etching. Accordingly, the dummy gate pattern 265 is entirely removed, a trench 195 is formed between the spacers 175, and the isolation layer 110, the active layer 134 and the sacrificial layer 132 are exposed.

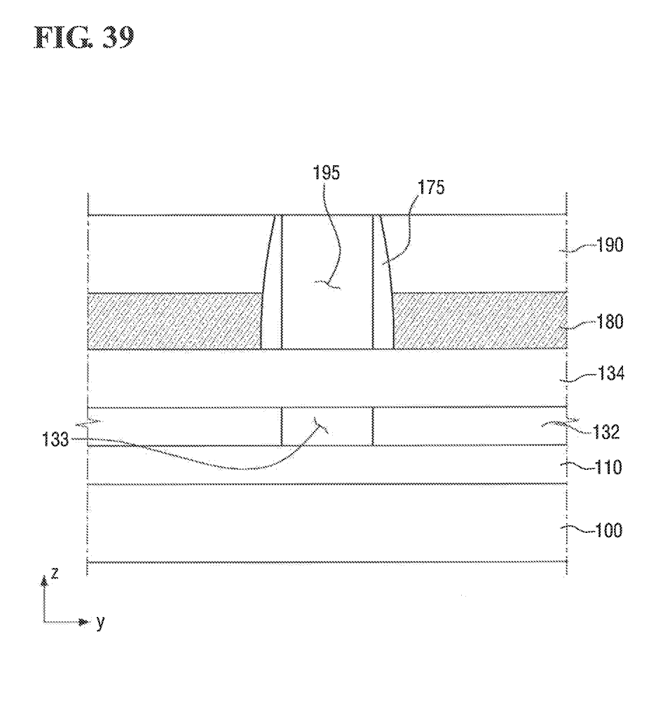

FIG. 39 is a cross-sectional view taken along ling A-A of FIG. 38. Referring to FIG. 39, the first region 431 (in FIG. 33) of the exposed sacrificial layer 132 is etched. Specifically, the sacrificial layer 132 on the lower portion of the exposed active layer 134 is removed using an etch selection ration of the active layer 134 and the sacrificial layer 132.

In an exemplary embodiment, the sacrificial layer 132 may include, for example, silicon germanium (SiGe). In this case, if the weight of the germanium (Ge) that forms the sacrificial layer 132 is higher than the weight of the silicon (Si), the etch selection ration of the silicon (Si) included in the active layer 134 may be heightened. Accordingly, the sacrificial layer 132 on the lower portion of the exposed active layer 134 can be removed, for example, through performing of the wet etching using hydrochloric acid (HCl). As a part of the sacrificial layer 132 is removed, a through-hole 133 that penetrates the sacrificial layer 132 may be formed.

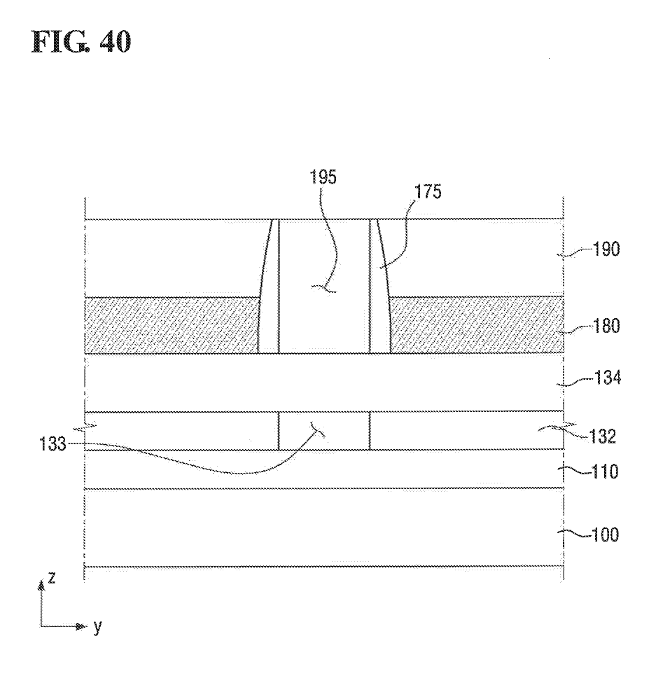

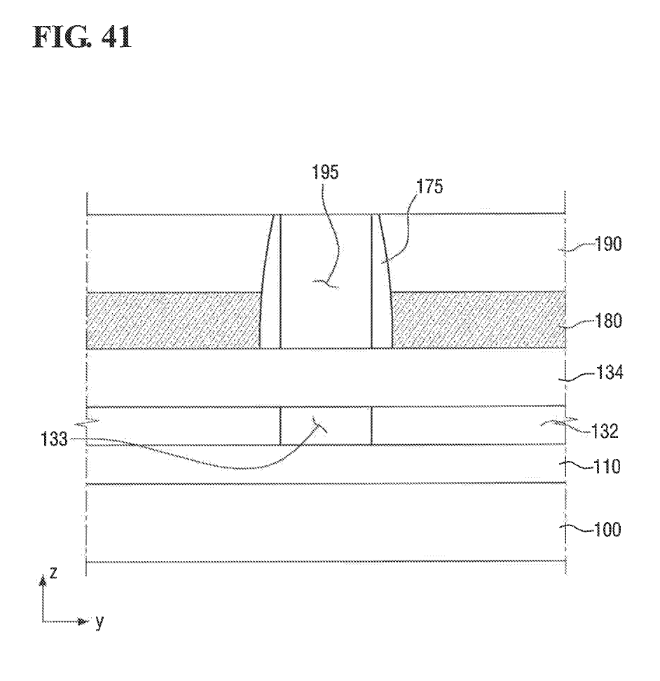

Then, referring to FIGS. 40 and 41, a gate insulating layer 160 is formed to completely surround the exposed active layer 134 (433 in FIG. 33), in this case, the gate insulating layer 160 may completely surround the upper surface, the side surface, and the lower surface of the active layer 134 through penetration of the sacrificial layer 132. Further, as illustrated, the gate insulating layer 160 may be formed to extend upward along the side wall of the spacer 175. Further, the gate insulating layer 160 may be formed even on the exposed isolation layer 110.

The gate insulating layer 160 may include a high-k material having higher dielectric constant than the dielectric constant of the silicon oxide layer. For example, the gate insulating layer 160 may include hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate, but is not limited thereto.

Then, referring to FIGS. 42 and 1 to 3, a gate electrode is formed on the gate insulating layer 160. The gate electrode may be formed to surround the remaining portion except for the lower portion of the active layer 134, and an air gap 150 may be formed in the lower portion of the active layer 134. Specifically, the gate electrode may surround the upper surface and both side surfaces of the active layer only, but need not be formed on the lower portion of the active layer 134. That is, the air gap 150 may be formed on the lower portion of the active layer 134 that is not filled with the gate electrode. Accordingly, a semiconductor device as illustrated in FIGS. 1 to 3 may be fabricated.

In the above-described manufacturing method, in the case where the sacrificial layer 132 (in FIG. 4) and the active layers 134 and 138 (in FIG. 4) are repeated to be alternately laminated on the substrate 100, the semiconductor device 2 as illustrated in FIGS. 4 to 6 may be fabricated.

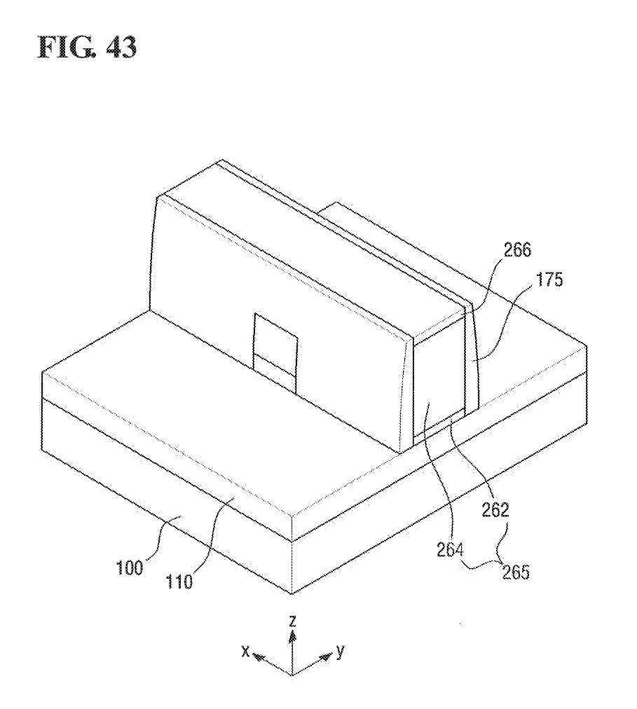

FIGS. 43 to 45 are views of intermediate steps explaining a method for fabricating a semiconductor device according to an exemplary embodiment of the present inventive concept.

To follow the process illustrated in FIG. 35, referring to FIG. 43, the second region 432 (in FIG. 33) of the sacrificial layer 132 and the second region 434 (in FIG. 33) of the active layer 134 are removed. However, for an epitaxial growth process to be described later, a part of the sacrificial layer 132 may remain as a seed layer. However, the present inventive concept is not limited thereto.

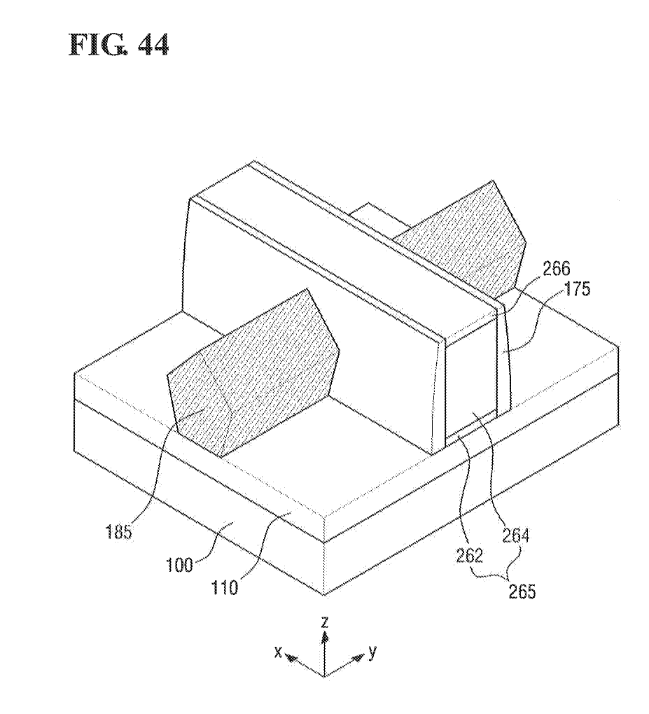

Then, referring to FIG. 44, the source/drain 185 is formed on the seed layer. That is, the source/drain 185 may be formed on both sides of the gate electrode. The source/drain 185 may come in contact with the upper surface of the isolation layer 110 and the side surface of the spacer 175. Further, the source/drain 185 may be connected to the active layer 134 and the sacrificial layer 132. In an exemplary embodiment, the source/drain 185 may be formed, for example, through the epitaxial growth process.

The source/drain 185 is exemplarily illustrated to be in a pentagonal shape, but is not limited thereto. That is, through adjustment of the processing conditions of the epitaxial process to form the source/drain 185, the source/drain 185 may be in various shapes, such as a diamond shape, a rectangular shape, and a hexagonal shape.

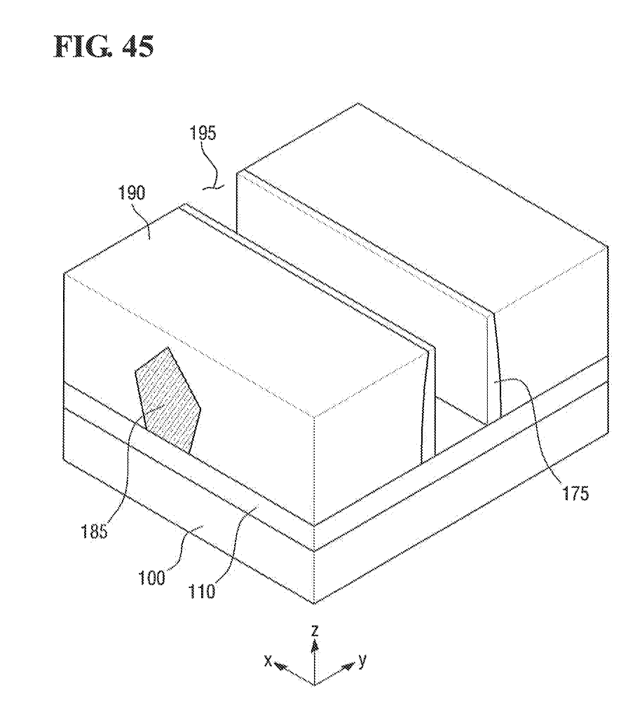

Then, referring to FIG. 45, an interlayer insulating layer 190 is formed on the resultant material on which the source/drain 185 is formed. The interlayer insulating layer 190 may include an oxide layer, a nitride layer, and/or an oxynitride layer. However, the present inventive concept is not limited thereto.

Then, the interlayer insulating layer 190 is planarized until the upper surface of the dummy gate pattern 265 is exposed. As a result, the mask pattern 266 is removed, and the upper surface of the dummy gate pattern 265 may be exposed. Then, the dummy gate pattern 265, that is, the dummy gate insulating layer 262 and the dummy gate electrode 264, may be removed.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the present inventive concept.

What is claimed is:

1. A semiconductor device comprising:
a sacrificial layer on a substrate;
an active layer on the sacrificial layer;
a gate insulating layer and a gate electrode surrounding a part of the active layer;
a spacer disposed on at least one side of the gate electrode;
a source or drain separated from the gate electrode by the spacer and disposed on the substrate; and
an air gap disposed between a lower portion of the active layer and the sacrificial layer,
wherein the sacrificial layer is disposed on a lower portion of the source or drain and is not disposed on a lower portion of the gate electrode.

2. The semiconductor device of claim 1, wherein the source or drain surrounds the active layer.

3. The semiconductor device of claim 1, wherein the height of the air gap is less than the height of the sacrificial layer, and
the height of the sacrificial layer is less than the height of the active layer.

4. The semiconductor device of claim 3, wherein the width of the air gap in a first direction is equal to the width of the gate electrode in the first direction.

5. The semiconductor device of claim 1, wherein the gate insulating layer is formed to completely surround the part of the active layer, and
the gate electrode is formed on an upper surface and both side surfaces of the part of the active layer, but is not formed on a lower surface thereof.

6. The semiconductor device of claim 1, wherein the sacrificial layer includes a first sacrificial layer and a second sacrificial layer positioned over the first sacrificial layer,
the active layer includes a first active layer positioned between the first sacrificial layer and the second sacrificial layer and a second active layer positioned on the second sacrificial layer, and
the air gap includes a first air gap positioned between the first active layer and the substrate and a second air gap positioned between the first active layer and the second active layer.

7. The semiconductor device of claim 1, wherein the lower portion of the source or drain is disposed to be lower than the lower portion of the active layer, and
the active layer is not disposed on the lower portion of the source or drain.

8. The semiconductor device of claim 7, wherein the sacrificial layer includes a first sacrificial layer and a second sacrificial layer positioned on the first sacrificial layer,
the active layer includes a first active layer positioned between the first sacrificial layer and the second sacrificial layer and a second active layer positioned on the second sacrificial layer, and
the air gap includes a first air gap positioned between the first active layer and the substrate and a second air gap positioned between the first active layer and the second active layer.

9. The semiconductor device of claim 1, wherein the gate electrode includes tungsten (W), and
the sacrificial layer is formed with a thickness of about 2 nm to about 4 nm.

10. The semiconductor device of claim 1, wherein the active layer and the sacrificial layer include a semiconductor material.

11. The semiconductor device of claim 10, wherein the active layer includes silicon (Si), and
the sacrificial layer includes silicon germanium (SiGe).

12. The semiconductor device of claim 1, further comprising a fin positioned on the substrate and positioned on a lower portion of the sacrificial layer,
wherein the air gap overlaps the fin.

13. A semiconductor device comprising:
a substrate having a first region and a second region;
a first nanowire transistor disposed on the first region; and
a second nanowire transistor disposed on the second region,
wherein the first nanowire transistor includes:
a first sacrificial layer formed on the substrate;
a first active layer formed on the first sacrificial layer;
a first gate electrode formed to surround a part of the first active layer; and
a first air gap formed between a lower portion of the first active layer and the first sacrificial layer, and
wherein the second nanowire transistor includes:
a second sacrificial layer formed on the substrate and including a material that is different from a material of the first sacrificial layer;
a second active layer formed on the second sacrificial layer;
a second gate electrode formed to surround a part of the second active layer; and
a second air gap formed between a lower portion of the second active layer and the second sacrificial layer.

14. The semiconductor device of claim 13, wherein the first sacrificial layer includes a semiconductor material,
the second sacrificial layer includes an insulating layer,
the first nanowire transistor includes a PMOS transistor, and
the second nanowire transistor includes an NMOS transistor.

15. The semiconductor device of claim 13, wherein the first nanowire transistor includes the first sacrificial layer, the first active layer, and the first air gap, and
the second nanowire transistor includes a plurality of the second sacrificial layers, a plurality of the second active layers, and a plurality of the second air gaps.

16. A semiconductor device comprising:
a sacrificial layer on a substrate;
an active layer on the sacrificial layer;
a gate insulating layer completely surrounding a part of the active layer
a gate electrode on the gate insulating layer;
a spacer disposed on at least one side of the gate electrode;
a source or drain separated from the gate electrode by the spacer and disposed on the substrate; and
an air gap disposed between a lower portion of the active layer and the sacrificial layer,
wherein the sacrificial layer is not disposed on a lower portion of the gate electrode.

17. The semiconductor device of claim 16, wherein a height of the air gap is less than a height of the sacrificial layer, and
the height of the sacrificial layer is less than a height of the active layer.

18. The semiconductor device of claim 17, wherein a width of the air gap in a first direction is equal to a width of the gate electrode in the first direction.

19. The semiconductor device of claim 16, wherein the sacrificial layer includes a first sacrificial layer and a second sacrificial layer positioned over the first sacrificial layer,
the active layer includes a first active layer positioned between the first sacrificial layer and the second sacrificial layer and a second active layer positioned on the second sacrificial layer, and
the air gap includes a first air gap positioned between the first active layer and the substrate and a second air gap positioned between the first active layer and the second active layer.

20. The semiconductor device of claim 16, further comprising a fin positioned on the substrate and positioned on a lower portion of the sacrificial layer,
wherein the air gap overlaps the fin.
